(19) United States
(12) Patent Application Publication
(10) Pub. No.: US 2011/0042124 A1
(43) Pub. Date: Feb. 24, 2011

(54) MULTILAYER WIRING SUBSTRATE HAVING CAVITY PORTION

(75) Inventors: Jun Matsui, Shiga (JP); Shingetsu Yamada, Shiga (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Mitsubishi Plastics, Inc., Tokyo (JP)

(21) Appl. No.: 12/745,651

(22) PCT Filed: Dec. 3, 2008
(86) PCT No.: PCT/JP08/71985

§ 371 Date: Nov. 3, 2010

(30) Foreign Application Priority Data
Dec. 5, 2007 (JP) 2007-314619

(51) Int. Cl. H01B 17/00; H05K 1/00; H05K 3/06; H05K 3/00

(52) U.S. Cl. 174/157; 174/258; 216/17; 156/182

(57) ABSTRACT

The present invention provides a multilayer wiring substrate comprising: a plurality of wiring substrate laminated each other; and a cavity portion. In the multilayer wiring substrate, a wiring substrate 1 being arranged along the bottom face of the cavity portion and a wiring substrate 2 being arranged at an upper layer side of the wiring substrate 1, the wiring substrate 1 and/or the wiring substrate 2 respectively comprising an insulating base material having a predetermined properties, the wiring substrate 2 being provided with a cavity hole. Thus, it is possible to provide a multilayer wiring substrate having a cavity portion and even a function of reflector.

### TECHNICAL FIELD

The present invention relates to a semiconductor chip, particularly relates to a multilayer wiring substrate having a cavity portion (i.e. hole, recess) for mounting light-emitting diodes (LED elements).

### BACKGROUND ART

The use of light-emitting diode (LED) attracting attention as a next generation light source has been steadily expanding to the fields such as liquid crystal display (LCD) backlighting, automobile lamp, and illumination. As a package substrate on which LEDs are mounted, there is a chip LED obtained by: directly mounting LED elements on a pattern of a printed wiring board formed from a white copper foil laminated plate and then, sealing them with a transparent silicon resin or an epoxy resin; or a chip LED produced by: insert-molding a white resin as a reflecter to a metal frame; directly mounting LED elements on a metal frame portion surrounded by a white resin reflector; and then setting the sealing resin inside the reflector. These chip LED packages have been mounted by soldering on a mother board of an electronic device by electronic device assembly manufacturer for practical application as a commercial product. In addition, these days, since highly-bright white LED has been developed, for the use of future general lighting, the LED elements are sometimes mounted directly on the mother wiring board itself for the use of lighting.

As an insulating base material for LED-mounted package substrate, in a case of white copper foil laminated plate, a glass-cloth/titanium oxide-filled white bismaleimide-triazine resin, a white epoxy resin, or a ceramic substrate is used. On the other hand, in a case of insert molding, a glass fiber-added or a titanium oxide-added white polyamide-based resin is used. The white bismaleimide-triazine resin, the white epoxy resin, and the white polyamide-based resin show yellow discoloration due to the heat at a time of substrate-fabricating process such as reflow step or due to the oxidative decomposition of the resin itself by the heat of LEDs during the operation, thereby the reflectance declines with age. When using a ceramic substrate, the problem of yellow discoloration does not happen; however, the ceramic substrate tends to be broken whereby it is difficult to produce a larger-sized substrate. Moreover, from the aspect of substrate structure, since the glass-cloth/titanium oxide-added white bismaleimide-triazine resin and the white epoxy resin contain a glass cloth, it is difficult to form a thinner substrate, so that conventional commercially available substrates have at least about 40 μm in thickness. In addition, ceramic substrate cannot maintain a certain mechanical strength, so that the thickness is usually about 400 μm and it is difficult to form a thinner substrate. In a case of insert forming type, although reflection efficiency may be raised by a reflector of the white polyamide-based resin, the reflector has a thickness of several hundred micrometers, which inhibits formation of thinner substrate. Because of the dam effect of the reflector, the insert forming type exhibits good workability in resin sealing, on the one hand; there still exist problems of adhesiveness between a metal frame and a resin.

Thus, a substrate for mounting LED which can be formed into a thinner one, can efficiently reflect lights emitted from LEDs, and can show little decline in reflectance under a high heat-load environment, has been demanded.

To these problems, a cavity substrate structure is proposed. As a method for forming a cavity portion in a substrate, there may be spot facing or drawing of the substrate. When adopting spot facing, restriction of the pattern designing and scraps produced at a time of processing become the problems. On the other hand, when adopting the method of drawing using punches and dies, the cavity structure in accordance with the specification cannot be formed or bulging portion may be formed on the back side of the substrate. Patent document 1 proposes a substrate having a cavity which comprises a thermosetting resin and which can also function as a reflector.
Patent Document 1: Japanese Patent Application Laid-Open (JP-A) No. 8-083930

### DISCLOSURE OF THE INVENTION

### Problems to be Solved by the Invention

In the chip LED-mounted substrate of Patent document 1, by mounting LEDs on a substrate having a cavity portion, it becomes possible to make the substrate thinner and possible to efficiently reflect the light emitted from LEDs forward to improve the frontal brightness. However, since the cavity portion is formed by spot facing, scraps (or burrs) of the reinforcement such as glass cloth sometimes project like beards; moreover, forming the cavity portions by spot facing requires cost, time and effort, which are problematic. Further, by the heat at a time of mounting step (i.e lead-free solder reflow step) or of actual operation, the substrate material tends to discolor and the reflectance tends to decline.

Accordingly, an object of the present invention is to provide an LED-mounted substrate which does not cause oxidative decomposition of resin itself by heat at a time of substrate fabricating process (such as reflow step) and actual operation, shows high reflection efficiency, and can be formed into a thinner substrate.

### Means for Solving the Problems

Hereinafter, the present invention will be described. In order to make the understanding of the present invention easier, reference numerals of the attached drawings are quoted in brackets; however, the present invention is not limited by the embodiments shown in the drawings.

The first aspect of the present invention is a multilayer wiring substrate (200, 200A) comprising: a plurality of wiring substrates laminated each other; and a cavity portion (220), in the multilayer wiring substrate, at least one layer of a wiring substrate 1 (100a) being arranged at least along the bottom face of the cavity portion and at least one layer of a wiring substrate 2 (100A) being arranged at an upper layer side of the wiring substrate 1 (100a), the wiring substrate 1 (100a) and/or the wiring substrate 2 (100A) respectively comprising an insulating base material (10) which comprises a inorganic filler-containing thermoplastic resin composition as a main component and which has an average reflectance of 70% or more in a wavelength range of 400-800 nm and a decreasing rate in reflectance of 10% or less in a wavelength range of 470 nm after thermal treatment at 200° C. for 4 hours, the wiring substrate 2 (100A) being provided with a cavity hole (15).

To the multilayer wiring substrate (200, 200A) having the cavity portion (220) of the invention, LED elements can be mounted. In addition, since the cavity portion is formed not by spot facing but by laminating wiring substrates (100A) having a cavity hole followed by thermocompression bonding thereof, it is possible to efficiently form a substrate having a cavity. Moreover, even a small-sized cavity portion (220) and a complexly-shaped cavity portion (220) can be easily produced.

The second aspect of the present invention is a multilayer wiring substrate (200C, 200D) comprising: a plurality of wiring substrates laminated each other; and a cavity portion (220), in the multilayer wiring substrate, at least one layer of a wiring substrate 1 (100c) being arranged at least along the bottom face of the cavity portion and at least one layer of a wiring substrate 2 (100C) being arranged at an upper layer side of the wiring substrate 1 (100c), the wiring substrate 1 (100c) and/or the wiring substrate 2 (100C) respectively comprising an insulating base material (10) which comprises a inorganic filler-containing thermoplastic resin composition as a main component and which has an average reflectance of 70% or more in a wavelength range of 400-800 nm and a decreasing rate in reflectance of 10% or less in a wavelength range of 470 nm after thermal treatment at 200° C for 4 hours, and which further comprises an adhesive layer (40) containing a thermosetting resin composition as a main component and being arranged on at least one surface of the insulating base material (10), the wiring substrate 2 (100c) being provided with a cavity hole (15).

The multilayer wiring substrate (200C, 200D) according to the second aspect of the invention not only exhibits the effect of the first aspect of the invention but also exhibits excellent interlayer adhesiveness between respective neighboring layers due to the lamination of wiring substrates having an adhesive layer (40) containing a thermosetting resin composition as a main component; so, it is possible to provide a multilayer wiring substrate which exhibits excellent electronic connection between these wiring substrates. Moreover, the multilayer wiring substrate (200C, 200D) according to the second aspect of the invention can be formed by batch lamination employing thermocompression bonding; it can also be fabricated by sequential lamination employing thermocompression bonding.

In the first and second aspects of the invention, the plurality of the wiring substrate (100A, 100C) arranged at the upper side has a cavity hole of different size from each other so that it is possible to form a mode (200A, 200D) where the diameter of the cavity hole is expanded toward the upper layer side. Due to this, it is possible to have a side view of the cavity portion (220) in a staircase pattern, thereby possible to have various modes for mounting LED elements in the cavity portion. Moreover, by upwardly enlarging the diameter of the cavity portion, it is possible to reflect the light of LEDs forward more efficiently and in a wider area, therefore brightness of the front face can be improved. For instance, as shown in FIG. 1(c), there may be a mode where two LED elements (240) are mounted on the bottom face of the cavity portion (220) and the LED elements are respectively connected by a bonding wire with the conductive patterns (20) provided on the side surface of the cavity portion.

In the first and second aspects of the invention, the thermoplastic resin composition is preferably a mixed composition which comprises a polyarylketone resin and an amorphous polyetherimide resin and which has a crystal melting peak temperature (Tm) of 260° C. or more. When using these resins, it is possible to integrate the wiring substrates (100a, 100A, 100B, 100c, 100C, 100D) by thermocompression bonding to form a multilayer wiring substrate (200, 200A, 200C, 200D, 200E, 200F). In addition, by metal diffusion bonding of the conductive paste composition in via hole(s), resistance of the via hole can be controlled at an extremely low level; hence, it is possible to obtain a multilayer wiring substrate which exhibits excellent thermal resistance under moisture absorption, connection reliability, and adhesive strength of the conductor.

In the first and second aspects of the invention, preferably, the wiring substrates 1 and 2 are independently either a wiring substrate where a conductive pattern is formed on at least one surface of the insulating base material and an interlayer wiring is formed in the insulating base material to connect electrically in the thickness direction, or another wiring substrate where an interlayer wiring only is formed in the insulating base material to connect electrically in the thickness direction. As the method for forming the interlayer wiring, for example, there may be copper plating to through hole(s) and filling a conductive paste or solder balls in a through hole or an inner via hole; among them, a method using a conductive paste is preferable.

In the first and second aspects of the invention, preferably, the conductive paste composition to be filled as an interlayer wiring comprises a conductive powder and a binder component, wherein the mass ratio of the conductive powder to the binder component is 90/10 or more and below 98/2; the conductive powder comprises a first alloy particle and a second metal particle, wherein the first alloy particle is a non-lead solder particle having a melting point of 130° C. or more and below 260° C., the second metal particle is at least one selected from the group consisting of Au, Ag, and Cu, and the mass ratio of the first alloy particle to the second metal particle is 76/24 or more and below 90/10; the binder component is a mixture of thermosetting polymerizable monomers, and the melting point of the non-lead solder particle is within the range of setting temperature of the binder component; storage elastic modulus of the thermoplastic resin composition constituting the insulating base material at the melting point of the non-lead solder particle is 10 MPa or more and below 5 GPa. By using such a conductive paste composition, metal diffusion bonding in the via hole 30 and between the via hole 30 and the conductive pattern 20 can be effectively attained.

In the first and second aspects of the invention, the lamination of the wiring substrates (100A, 100a, 100B, 100C, 100c, 100D) is preferably carried out by thermocompression bonding; it is particularly preferably carrired out under a condition of: 180° C. or more and below 320° C., 3 MPa or more and below 10 MPa for 10 to 120 minutes. By performing the thermocompression bonding under the condition, the metal diffusion bonding can be more effectively attained.

In the first and second aspects of the invention, the refractive index of the inorganic filler contained in the thermoplastic resin composition is preferably 1.6 or more. The inorganic filler is preferably titanium oxide. The thermoplastic resin composition, preferably, further comprises an inorganic filler having an average diameter of 15 μm or less and an average aspect ratio of 30 or more.

The third aspect of the present invention is a method for fabricating a multilayer wiring substrate having a cavity portion by laminating a plurality of wiring substrates, comprising: a step 1 for laminating one or more layers of wiring substrate 1 (100a) arranged on the bottom face of a cavity portion; a step 2 for laminating one or more layers of wiring substrate 2 (100A) arranged on the wiring substrate 1 (100a); and a step 3 for integrating these laminated wiring substrates by thermocompression bonding, wherein the wiring substrate 1 (100a) and/or the wiring substrate 2 (100A) respectively comprise an insulating base material (10) which comprises an inorganic filler-containing thermoplastic resin composition as a main component and which have an average reflectance of 70% or more in a wavelength range of 400-800 nm and a decreasing rate in reflectance of 10% or less in a wavelength range of 470 nm after thermal treatment at 200° C. for 4 hours, and the wiring substrate (100A) further comprises a cavity hole (15).

The fourth aspect of the present invention is a method for fabricating a multilayer wiring substrate (200C, 200D) having a cavity portion by laminating a plurality of wiring substrates, comprising the steps of: forming a wiring substrate 1 (100c) comprising: an insulating base material 1 (10), an adhesive layer (40) containing a thermosetting resin composition as a main component and being provided on at least one surface of the insulating base material 1 (10), and a conductive pattern (20) provided on the adhesive layer (40) and/or the insulating base material 1 (10); forming a monolayer wiring substrate 2 (100C) or sequentially forming a multilayer wiring substrate 2 (100C) by once or repeatedly: superposing on the wiring substrate 1 (100c) an insulating base material 2 (50C) where an adhesive layer (40) comprising a thermosetting resin composition as a main component is provided on at least one surface and in which a cavity hole (15) is formed; superposing a copper foil (22) on the insulating base material 2 (50C); integrating these layers by thermocompression bonding; and then, etching the copper foil (22) to produce a conductive pattern, wherein the insulating base material 1 (10) and/or the insulating base material 2 (50C) independently comprise an inorganic filler-containing thermoplastic resin composition as a main component and which have an average reflectance of 70% or more in a wavelength range of 400-800 nm and a decreasing rate in reflectance of 10% or less in a wavelength range of 470 nm after thermal treatment at 200° C. for 4 hours.

The fifth aspect of the present invention is a method for fabricating a multilayer wiring substrate (200C, 200D) having a cavity portion by laminating a plurality of wiring substrate, comprising the steps of: sequentially forming two or more wiring substrates 1 (100c) by once or repeatedly: forming a wiring substrate 1 (100c) comprising: an insulating base material 1 (10), an adhesive layer (40) containing a thermosetting resin composition as a main composition and provided on at least one surface of the insulating base material 1 (10), and a conductive pattern (20) provided on the adhesive layer (40) and/or the insulating base material 1 (10); superposing on the wiring substrate 1 an insulating base material 1 (50) where an adhesive layer (40) comprising a thermosetting resin composition as a main component is provided on at least one surface; superposing a copper foil (22) on the insulating base material 1 (50); integrating these layers by thermocompression bonding; and then, etching the copper foil (22) to produce a conductive pattern (20), further, forming a monolayer wiring substrate 2 or sequentially forming a multilayer wiring substrate 2 by once or repeatedly: superposing on the wiring substrate 1 (100c) an insulating base material 2 (50C) where an adhesive layer (40) comprising a thermosetting resin composition as a main component is provided on at least one surface and in which a cavity hole (15) is formed; superposing a copper foil (22) on the insulating base material 2 (50C); integrating these layers by thermocompression bonding; and then, etching the copper foil (22) to produce a conductive pattern (20), wherein the insulating base material 1 (10, 50) and/or the insulating base material 2 (50C) independently comprise an inorganic filler-containing thermoplastic resin composition as the main component and have an average reflectance of 70% or more in a wavelength range of 400-800 nm and a decreasing rate in reflectance of 10% or less in a wavelength range of 470 nm after thermal treatment at 200° C. for 4 hours.

Alternatively, the multilayer wiring substrate (200C, 200D) can be fabricated by batch lamination of the wiring substrates (100c, 100C, 100D) each having an adhesive layer (40).

According to the third to the fifth aspects of the invention, the multilayer wiring substrate (200, 200A, 200C, 200D, 200E, 200F) having a cavity portion (220) can be formed not by spot facing but by thermocompression bonding. Therefore, the fabrication process can be simplified and the multilayer wiring substrate having a cavity portion can be efficiently fabricated. In addition, the shape of cavity hole (15) of the wiring substrate can be freely designed so that even a small-sized or complexly-shaped cavity portion (220) can be easily produced. Further, since a wiring substrate that can reflect light can be formed at a predetermined position, when mounting LED elements thereon, the wiring substrate can function as a reflector.

### Effects of the Invention

According to the present invention, (1) the multilayer wiring substrate can be compact and lower profile, thereby LED elements can be densely-mounted; (2) the multilayer wiring substrate comprises a cavity portion for mounting LED elements; (3) even a small-sized cavity portion or a complexly-shaped cavity portion can be efficiently formed; and (4) the wiring substrate exhibits extremely low decreasing rate in reflectance under high reflectance characteristics and high temperature environment. So, by mounting LED elements and so on, it is possible to provide a multilayer wiring substrate having a cavity portion which also functions as a reflector.

### BRIEF DESCRIPTION OF THE DRAWINGS

FIG. 1(a) is a schematic view showing a layer structure according to a multilayer wiring substrate 200 of the present invention;

FIG. 1(b) is a schematic view showing a layer structure according to a multilayer wiring substrate 200A of the invention;

FIG. 1(c) is a schematic view showing a state where LED elements 240 are mounted on the multilayer wiring substrate 200A;

FIG. 1(d) is a schematic view showing a state where LED elements 240 are mounted on the multilayer wiring substrate 200 of the invention;

FIG. 2(a) is a schematic view illustrating a method for fabricating the wiring substrate 100a;

FIG. 2(b) is a schematic view illustrating a method for fabricating the wiring substrate 100A;

FIG. 3 is a schematic view showing a method for fabricating the multilayer wiring substrate 200;

FIG. 4 is a graph showing a development of elastic modulus of a binder component in a conductive paste composition filled in the via hole 30 by temperature increase;

FIG. 5 is a graph showing a development of elastic modulus of a particular thermoplastic resin composition constituting the insulating base material 10;

FIG. 6(a) is a schematic view showing a layer structure according to a multilayer wiring substrate 200C of the invention;

FIG. 6(b) is a schematic view showing a layer structure according to a multilayer wiring substrate 200D of the invention;

FIG. 7 is a schematic view illustrating a method for fabricating a wiring substrate 50D and a wiring substrate 100D;

FIG. 8 is a schematic view illustrating a method for fabricating a wiring substrate 50 and a wiring substrate 100c;

FIG. 9 is a schematic view illustrating a method for fabricating the multilayer wiring substrate 200C;

FIG. 10 is a schematic view illustrating a method for fabricating the multilayer wiring substrate 200D;

FIG. 11(a) is a schematic view showing a layer structure of a multilayer wiring substrate 200E;

FIG. 11(b) is a schematic view showing a layer structure of a multilayer wiring substrate 200F;

FIG. 12 is a schematic view illustrating a method for fabricating the multilayer wiring substrate 200E; and

FIG. 13 is a schematic view illustrating a method for fabricating the multilayer wiring substrate 200F.

### DESCRIPTION OF THE REFERENCE NUMERALS

10 an insulating base material exhibiting an average reflectance of 70% or more in a wavelength range of 400-800 nm and a decreasing rate in reflectance of 10% or less in a wavelength range of 470 nm after thermal treatment at 200° C. for 4 hours
10a insulating base material
11 insulating base material where a cavity hole is formed in the insulating base material 10
12 insulating base material where an adhesive layer is formed on the insulating base material 10
13 insulating base material where an adhesive layer is formed on the insulating base material 10a
15 cavity hole
20 conductive pattern
30 via hole
40 adhesive layer
100a, 100A, 100B, 100c, 100C wiring substrate
200, 200A, 200C, 200D, 200E, 200F multilayer wiring substrate
220 cavity portion
240 LED element
260 spacer
320 mold release film
340 stainless steel sheet

### BEST MODE FOR CARRYING OUT THE INVENTION

Hereinafter, the present invention will be described by way of the following embodiments shown in the drawings. It should be noted that in the invention, unless otherwise specified, the term “as a main component” means to allow inclusion of other components in the range which does not undermine the function of the main component. The content rate of the main component is not particularly limited; the main component (if a combination of two or more components is the main component, the total content) in the composition is usually 50 mass % or more, preferably 70 mass % or more, and particularly preferably 90 mass % or more (including 100 mass %)

<Multilayer Wiring Substrate 200, 200A>

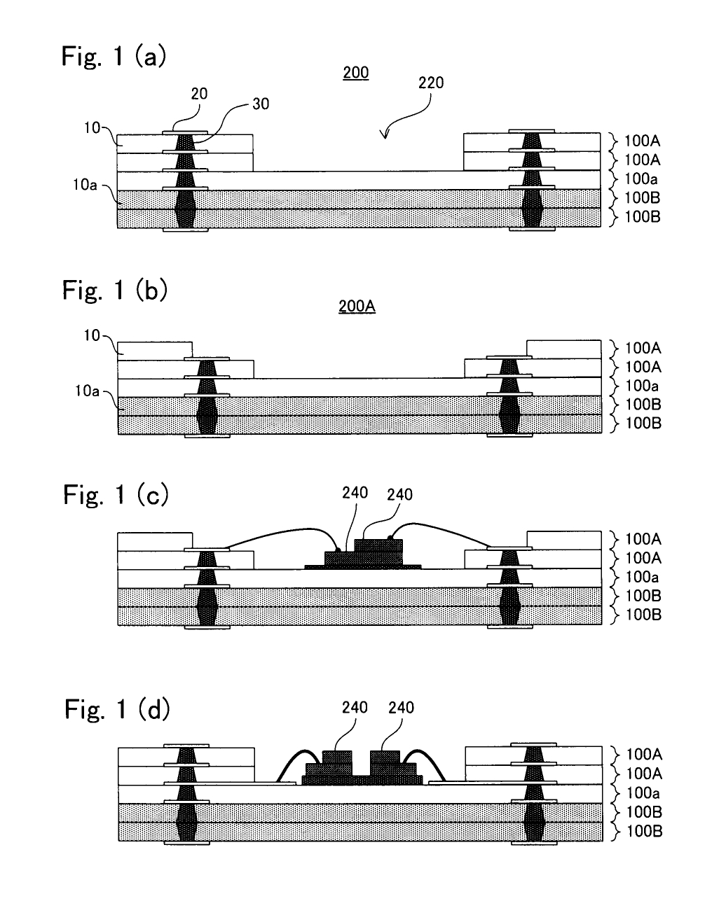

FIG. 1(a) and FIG. 1(b) show a schematic view showing a multilayer wiring substrate 200 and a multilayer wiring substrate 200A of the present invention, respectively; FIG. 1(c) and FIG. 1(d) show a schematic view showing a state where LED elements 240 are mounted on the multilayer wiring substrate 200A and a state where LED elements 240 are mounted on the multilayer wiring substrate 200, respectively.

The multilayer wiring substrates 200, 200A of the invention are the one comprising: a plurality of wiring substrates laminated each other, in the multilayer wiring substrate, a wiring substrate 1 being arranged at least along the bottom face of the cavity portion and a wiring substrate 2 being arranged at an upper layer side of the wiring substrate 1, the wiring substrate 1 and/or the wiring substrate 2 respectively comprising an insulating base material 10 which comprises a inorganic filler-containing thermoplastic resin composition as a main component and which has an average reflectance of 70% or more in a wavelength range of 400-800 nm and a decreasing rate in reflectance of 10% or less in a wavelength range of 470 nm after thermal treatment at 200° C. for 4 hours, further, the wiring substrate 2 being an insulating base material 11 having a cavity hole 15 formed in the insulating base material 10. A plurality of the wiring substrates 1 and 2 can be laminated. Then, predetermined via holes 30 as the interlayer wiring and conductive patterns 20 are formed in/on the insulating base materials 10 and 11 to form the wiring substrate 100a and the wiring substrate 100A; these are multi-stratified to mount LED elements thereon.

In an embodiment shown in FIG. 1(a), a wiring substrate 1 arranged along the bottom face of the cavity portion is composed of a wiring substrate 100a, and all the wiring substrates 2 arranged at an upper side of the wiring substrate 1 are composed of wiring substrates 100A. When mounting LED elements in the cavity portion, by having such a layer structure, the multilayer wiring substrate can significantly function as a reflector; thus, it is preferable. Moreover, in the structure, wiring substrates 100B are arranged underneath the wiring substrate 1, such a structure is also available. Alternatively, a wiring substrate 100b where a cavity hole is formed in the wiring substrate 100B may be arranged at an upper side of the wiring substrate 1. It should be noted that the wiring substrate 100B is the one composed of an insulating base material 10a containing a thermoplastic resin composition as a main component. On the other hand, in the embodiment shown in FIG. 1(b), by changing the size of the cavity hole 15 of the wiring substrate 100A, side geometry of the cavity portion 220 is changed.

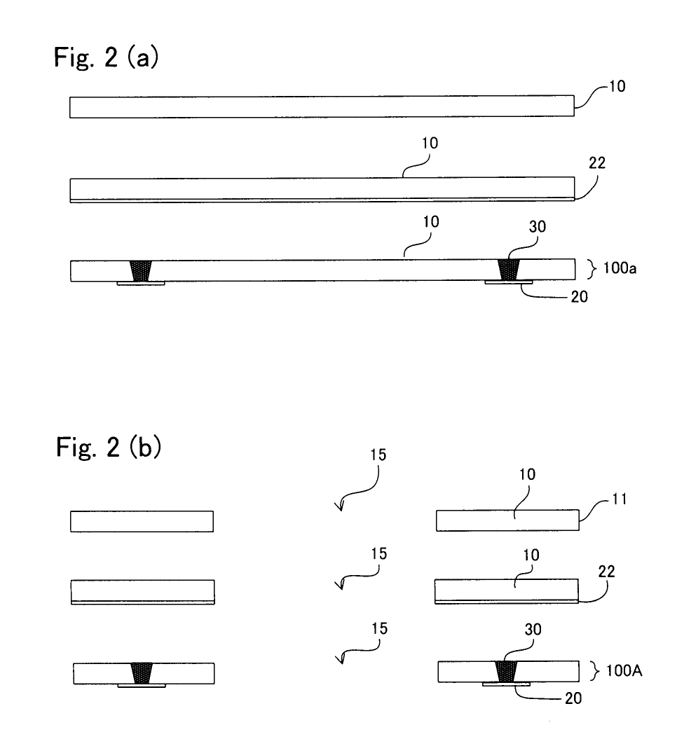

The multilayer wiring substrate 200, 200A of the invention, as shown in FIGS. 1(a) and 1(b), is obtained by: forming predetermined conductive patterns and via holes to be the interlayer wiring on/in the insulating base materials 10 and 11 (see FIG. 2(b)) to form the wiring substrate 100a and the wiring substrate 100A; laminating these layers; and mounting LED elements thereon. In the embodiment shown in FIGS. 1(a) and 1(b), although a conductive pattern 20 and a via hole 30 to be an interlayer wiring which penetrates the insulating base material in the thickness direction are formed on/in an insulating base material 10 in advance, it is also possible to obtain the multilayer wiring substrate 200, 200A by: forming a predetermined conductive pattern 20 on insulating base materials 10 and laminating them each other; and then forming via holes 30. It is also possible to connect the layers electrically by only using via holes 30.

As above, the multilayer wiring substrate 200, 200A of the invention may have various lamination styles; the lamination styles include the following structures:
1. wiring substrate 100A/wiring substrate 100a
2. wiring substrate 100A . . . /wiring substrate 100a
3. wiring substrate 100A . . . /wiring substrate 100b/wiring substrate 100a
4. wiring substrate 100A/wiring substrate 100B
5. wiring substrate 100b/wiring substrate 100a
6. wiring substrate 100b . . . /wiring substrate 100a
7. wiring substrate 100b . . . /wiring substrate 100A/wiring substrate 100a
8. wiring substrate 100A/wiring substrate 100a/wiring substrate 100B
9. wiring substrate 100A/wiring substrate 100a/wiring substrate 100a
10. wiring substrate 100A/wiring substrate 100a/wiring substrate 100a . . .
   (it should be noted that the term “wiring substrate 2/wiring substrate 1” means that the wiring substrate 1 (i.e. the member after the slash) is arranged at the lower side of the wiring substrate 2 (i.e. the member before the slash), and “. . . ” means that a plurality of the layer are laminated.).

As shown above, it is possible to arrange the wiring substrate 100B along the bottom face of the cavity portion and possible to laminate the wiring substrate 100b, where a cavity hole 15 is formed in the wiring substrate 100B, at an upper layer side (for example, the structures 3 to 7). Moreover, it is possible to laminate the wiring substrate 100a at a lower side (for example, the structures 9 and 10); further, it is possible to form all the layers by using the wiring substrate 100A and the wiring substrate 100a only (for example, the structures 1, 2, 9, and 10).

<Wiring Substrate 100a>

Hereinafter, the members constituting the wiring substrate 100a will be described. The wiring substrate 100a is the one where a predetermined conductive patterns and interlayer wirings are formed on an insulating base material 10 which comprises an inorganic filler-containing thermoplastic resin composition as a main component and which has an average reflectance of 70% or more in a wavelength range of 400-800 nm and a decreasing rate in reflectance of 10% or less in a wavelength range of 470 nm after thermal treatment at 200° C. for 4 hours. The wiring substrate 100a may be, for example, a wiring substrate 1 which is arranged along the bottom face of the cavity portion when built up a multilayer wiring substrate or a member arranged at the lower side of the wiring substrate which is arranged along the bottom face of the cavity portion.

The insulating base material 10 requires the decreasing rate in reflectance of 10% or less in a wavelength range of 470 nm after thermal treatment at 200° C. for 4 hours; among them, decreasing rate in reflectance in a wavelength range of 470 nm after thermal treatment at 260° C. for 5 minutes is preferably 10% or less.

The substantial reasons for the above conditions will be described as below. When fabricating an LED-mounted substrate, there are processes under high heat-load, such as a thermosetting process of sealant, e.g. conductive adhesive, epoxy resin, silicon resin (at 100-200° C. for several hours), soldering process (Pb-free solder reflow at a peak temperature of 260° C. for several minutes), and wire bonding process. On the other hand, under the environment of actual operation, due to the development of highly-bright LEDs and increase of heat-load to the substrates, the temperature at the periphery of LED elements sometimes exceed 100° C. Therefore, it is becoming more important to keep high reflectance under such a high heat-load environment, without causing discoloration. It should be noted that 470 nm is an average wavelength of blue LED.

Therefore, if the decreasing rate in reflectance in a wavelength range of 470 nm after thermal treatment under the above condition (i.e. at 200° C. for 4 hours and at 260° C. for 5 minutes) is 10% or less, decrease in reflectance both during the fabrication process and during actual operation can be inhibited; whereby the wiring substrate can be suitably used for an LED-mounted substrate. It is more preferably 5% or less, further more preferably 3% or less, and particularly preferably 2% or less.

### (Insulating Base Material 10)

The thermoplastic resin composition constituting the insulating base material 10 may be: a crystalline thermoplastic resin having a crystal melting peak temperature (Tm) of 260° C. or more; an amorphous thermoplastic resin having a glass transition temperature of 260° C. or more; or a composition comprising a liquid crystal polymer having a liquid crystal transition temperature of 260° C. or more.

Among them, as the thermoplastic resin composition, a crystalline thermoplastic resin having a crystal melting peak temperature of 260° C. or more is preferably used; particularly, a mixed composition which comprises a polyarylketone resin and an amorphous polyetherimide resin and which has a crystal melting peak temperature of 260° C. or more is preferably used.

Now, a mixed composition, which comprises a polyarylketone resin and an amorphous polyetherimide resin and which has a crystal melting peak temperature of 260° C. or more as a preferable thermoplastic resin composition for constituting the insulating base material 10, will be described. A polyarylketone resin and an amorphous polyetherimide resin are compatible, the mixed composition has a particular crystal melting peak temperature, and the crystal melting peak temperature is 260° C. or more. When using the mixed composition of the polyarylketone resin and the amorphous polyetherimide resin as the thermoplastic resin composition for constituting the insulating base material 10, in a case of forming the multilayer wiring substrate 200, adhesiveness between the neighboring layers can be favorable. Further, as described in detail below, by using the mixed composition of a polyarylketone resin and an amorphous polyetherimide resin, it is possible to attain metal diffusion bonding with the conductive paste filled in the via holes 30.

The polyarylketone resin is a thermoplastic resin containing, in its structural unit: an aromatic nucleus bond, ether bond, and ketone bond. The typical examples may be polyether ketone, polyether ether ketone, and polyether ketone ketone; among them, polyether ether ketone is preferable. The polyether ether ketone is commercially available as, for example, “PEEK 151G”, “PEEK 381G”, “PEEK 450G” (each of which is a commodity name of the product manufactured by Victrex plc.).

The amorphous polyetherimide resin is an amorphous thermoplastic resin containing, in its structural unit: an aromatic nucleus bond, ether bond, and imide bond. The amorphous polyetherimide resin is commercially available as, for example, “ULTEM CRS5001”, “ULTEM 1000” (each of which is a commodity name of the product manufactured by General Electric Company).

As the mixing ratio of the polyarylketone resin and the amorphous polyetherimide resin, in view of adhesiveness between the respective neighboring layers, preferably, 30 mass % or more and 80 mass % or less may be the polyarylketone resin; and the remaining portion may be a mixed composition of the amorphous polyetherimide resin and inevitable impurities. The content rate of the polyarylketone resin is more preferably 35 mass % or more and 75 mass % or less, further more preferably 40 mass % or more and 70 mass % or less. When the upper limit of the content rate regarding the polyarylketone resin is determined within the above range, it is possible to inhibit higher crystallization of the thermoplastic resin composition and it is also possible to inhibit decrease of adhesiveness at a time of forming multilayer substrate. On the other hand, when the lower limit of the content rate regarding the polyarylketone resin is determined within the above range, it is possible to inhibit low crystallization of the thermoplastic resin composition and also possible to inhibit decrease in thermal resistance in a reflow step of the multilayer wiring substrate.

The insulating base material 10 is formed by adding an inorganic filler to these resins to have an average reflectance of 70% or more in a wavelength range of 400-800 nm and a decreasing rate in reflectance of 10% or less in a wavelength range of 470 nm after thermal treatment at 200° C. for 4 hours. As the inorganic filler, one, whose refractive index is largely different from that of the thermoplastic resin as the base resin, is preferable. Namely, an inorganic filler having a high refractive index, 1.6 or more as the standard is preferable. Specifically, for example, calcium carbonate, barium sulfate, zinc oxide, titanium oxide, and titanates each having a refractive index of 1.6 or more are preferably used; titanium oxide is particularly preferable.

Titanium oxide shows significantly higher refractive index compared with other inorganic fillers and enables to enlarge the difference in refractive index from that of the thermoplastic resin as the base resin. Therefore, compared with the cases using other fillers, it is possible to obtain an excellent reflectivity with smaller dosage. Moreover, even when the film is made thinner, it is possible to obtain a white film which exhibits high reflectivity.

Titanium oxide may preferably be a crystalline titanium oxide such as anatase-type or rutile-type titanium oxide; among them, in view of enlarging difference in refractive index from that of the base resin, rutile-type titanium oxide is preferable.

Method for producing titanium oxide may be chlorine method and sulfuric acid method; in view of obtaining whiteness and light resistance, titanium oxide produced by chlorine method is preferably employed.

The titanium oxide is preferably the one of which surface is coated with an inactive inorganic oxide. By coating the surface of the titanium oxide with the inactive inorganic oxide, it is capable of inhibiting photocatalytic activity of the titanium oxide; thereby it is possible to inhibit deterioration of the film. Examples of the inactive inorganic oxide may preferably be at least one selected from the group consisting of silica, alumina, and zirconia. When these inactive inorganic oxides are used, it is possible to inhibit decrease of molecular weight and yellowing of the thermoplastic resin without deteriorating its high reflectivity when melting at a high-temperature.

To enhance dispersiveness of the titanium oxide in the thermoplastic resin, the surface of the titanium oxide is preferably treated by at least one inorganic compound selected from, for example, a siloxane compound and a silane coupling agent, or treated by at least one organic compound selected from, for example, polyol and polyethylene glycol. Particularly, in view of thermal resistance, a titanium oxide treated by a silane coupling agent is preferable.

The particle diameter of the titanium oxide is preferably 0.1-1.0 μm, more preferably 0.2-0.5 μm. When the particle diameter of the titanium oxide is within the above range, dispersiveness of the titanium oxide in the thermoplastic resin is favorable so that it is possible to form a dense interface with the thermoplastic resin, whereby high reflectivity can be attained.

The content of the titanium oxide based on 100 parts by mass of the thermoplastic resin composition is preferably 15 parts by mass or more, more preferably 20 parts by mass or more, and most preferably 25 parts by mass or more. Within the above range, favorable reflectivity can be obtained.

Into the thermoplastic resin composition, the following inorganic filler can be added. Specific examples thereof include: talc, mica, glassflake, boron nitride (BN), plate-type calcium carbonate, plate-type aluminum hydroxide, plate-type silica, and plate-type potassium titanate. These may be used alone or used in combination of two or more thereof. Particularly, a scale-type inorganic filler having an average particle diameter of 15 μm or less and an aspect ratio [(particle diameter)/thickness] of 30 or more is preferable because it can control the ratio of linear expansion coefficient in the planar direction and in the thickness direction at a lower level and can inhibit occurrence of cracks in the substrate at a time of thermal shock cycle test.

Examples of the filler having an average particle diameter of 15 μm or less and an average aspect ratio [(average particle diameter)/(average thickness)] of 30 or more include: an inorganic scale-type (plate-type) filler such as a synthetic mica, a natural mica (e.g. muscovite, phlogopite, sericite, and suzorite), a calcined natural or synthetic mica, boehmite, talc, illite, kaolinite, montmorillonite, vermiculite, smectite, and plate-type alumina; and scale-type titanates. Adding these filler is preferable because it is possible to control the linear expansion coefficient ratio at a lower level in the planar direction and the thickness direction. In addition, when considering light reflectivity, scale-type titanates are preferable because of its higher refractive index. These fillers can be used alone or used in combination of two or more thereof.

The content of the scale-type inorganic filler based on 100 parts by mass of the thermoplastic resin composition is preferably 10 parts by mass or more, more preferably 20 parts by mass or more, and particularly preferably 30 parts by mass or more. Within the above range, the linear expansion coefficient of the obtained white film can be lowered down to the predetermined range. To make a balance between the reflectance and the linear expansion coefficient, the above titanium oxide and the scale-type inorganic filler may preferably be mixed at an adequate ratio. The average linear expansion coefficient in the machine direction (MD: the direction of film flow) and the transverse direction (TD: the direction orthogonal to the film's flow direction) is preferably 35×10⁻⁶/° C. or less. When the average linear expansion coefficient is set within the range of 35×10⁻⁶/° C, or less, it is possible to show excellent effects such as good dimensional stability, high reflectance, and small decrease in reflectance even after thermal treatment. Depending on the kind of metal foil to be used, circuit patterns formed on both sides of the substrates, and laminate structure, more preferable range of the linear expansion coefficient may be approximately 10×10⁻⁶/° C. to 30×10⁻⁶/° C. By adjusting the average linear expansion coefficient within the range, it is possible to reduce problems such as curl and warp caused when laminating a metal foil or insufficiency of dimensional stability. In addition, the difference of the linear expansion coefficient between the MD and the TD is preferably 20×10⁻⁶/° C. or less, more preferably 15×10⁻⁶/° C. or less, and particularly preferably 10×10⁻⁶/° C. or less. By reducing anisotropy (the difference of the linear expansion coefficient between the MD and TD), there is no worry about curl and warp caused in the direction (MD or TD) showing larger linear expansion coefficient and no worry about insufficiency of dimensional stability.

To the thermoplastic resin composition constituting the insulating base material 10, in the range which does not undermine the property, various additives apart from other resins and inorganic fillers, such as stabilizer, ultraviolet absorber, light stabilizer, nucleating agent, coloring agent, lubricant, and flame retardant, may be adequately added. The method for adding these various additives including the inorganic fillers may be a known method such as the following methods (a) and (b).

Method (a) is a method comprising the steps of: preparing master batches by adding a highly-concentrated (typical content may be 10-60 mass %) various additives respectively to each base material (base resin) for the thermoplastic resin composition; adjusting the concentration of the individual master batches by mixing with the thermoplastic resin composition; finally, mechanically blending the mixture using a kneader or an extruder.

Method (b) is a method where a predetermined concentration of the various additives are directly mixed with the thermoplastic resin composition and the mixture is mechanically blended using a kneader or an extruder.

Between these methods, the method (a) is preferable in view of dispersiveness and workability. Moreover, to improve laminatability, the surface of the insulating base material 10 comprising the thermoplastic resin composition may be adequately treated by corona discharge.

The insulating base material 10 may be produced by a known method such as extrusion casting using T-die or calendaring; it is not particularly limited. However, in view of film-forming property and stable production of the sheet, extrusion casting using T-die is preferable. When forming conductive patterns 20 on the insulating base material 10, a copper foil 22 (see FIG. 2(a).) can be simultaneously adhered at a time of extruding the insulating base material 10.

The forming temperature of the insulating base material 10 by extrusion casting using T-die is adequately adjusted depending on, for example, flow property and film-forming property of the resin to be used; in a case of a mixed composition having a crystal melting peak temperature of 260° C. or more and comprising: polyarylketone resin and amorphous polyetherimide resin, the temperature is approximately 360-400° C. Moreover, at a time of film-forming of the insulating base material 10 by extrusion casting, it is necessary to form an amorphous film by quickly cooling the obtained film. By the quick cooling, the film shows a temperature region at around 170-230° C. where the elastic modulus falls so that it is capable of thermoforming and thermal fusion bonding within the temperature region. Specifically, the elastic modulus starts decreasing at around 170° C., then, thermoforming and thermal fusion bonding can become possible at around 200° C. FIG. 5 is a graph showing a development of elastic modulus of a mixed composition containing a polyether ether ketone resin and an amorphous polyetherimide resin by temperature. It should be noted that the graph of FIG. 5 is obtained by measuring elastic moduli at a rate of temperature increase of 3° C./minute. If the elastic moduli are measured at a rate of temperature increase of 10° C./minute, the transition from amorphous phase to crystalline phase delays; thereby the elastic modulus at around 230° C. becomes the lowest.

### (Conductive Pattern 20)

When mounting LED elements, a predetermined electroconductive circuit is formed on the insulating base material 10 and is connected with the LED elements. A method for forming the electroconductive circuit may be an usual method for forming a circuit pattern, such as: a method to form a conductive pattern 20 by adhering a copper foil 22 on the insulating base material 10 by thermocompression bonding and then etching the copper foil; a method of direct lamination of the copper foil 22 when obtaining a film of insulating base material 10 by extrusion; or a method for forming a conductive pattern 20 by forming a resist on the insulating base material 10 and plating thereof. It should be noted that as described below, the insulating base material 10 as a preferable embodiment of the invention is processed into an amorphous film by rapid cooling, so that it is possible to carry out thermocompression bonding at a relatively low temperature. As the metal for forming the conductive pattern 20, for example, Au, Ag, and Cu can be used as metals of small electrical resistance. Among them, in view of low cost and a lot of past record having been used as a conductive pattern for wiring substrate, Cu is preferably used.

### (Via Hole 30)

To electrically connect the neighboring wiring substrates, electrically-connecting interlayer wiring is formed in the insulating base material in its thickness direction. Examples of the method for forming the interlayer wiring include: a method of copper plating in the through hole; a method of filling in a through hole and/or an inner via hole; a method of filling a conductive paste or a solder ball; and a method of applying an anisotropically conductive material using an insulating layer containing fine conductive particles. Among them, when employing the method of filling in a through hole and/or an inner via hole using the following conductive paste composition, a high-density wiring can be attained, thus it is preferable.

The conductive paste composition contains a conductive powder and a binder component; the conductive powder is preferably composed of first alloy particles and second metal particles. The first alloy particle is a non-lead solder particle having a melting point of 180° C. or more and below 260° C. Examples of the non-lead solder particle include: Sn, Sn—Ag, Sn—Cu, Sn—Sb, Sn—Bi, Sn—In, Sn—Ag—Cu, Sn—Ag—C—Bi, Sn—Ag—In, Sn—Ag—In—Bi, Sn—Zn, Sn—Zn—Bi, Sn—A—Cu—Sb, and Sn—Ag—Bi. These non-lead solder particles are reliable in view of the effect of diffusing tin. As the first alloy particle, a mixture of two or more of these non-lead solder particles may be used.

The second metal particle may be at least one metal particle selected from the group consisting of Au, Ag, and Cu. The second metal particle is a particle formed by a metal of small electrical resistance, which has a function of electric conductivity of the via hole 30. Moreover, the second metal particle has a higher melting point than that of the first alloy particle so that it has a function of keeping viscosity of the conductive paste composition at a time of heating.

The mixing ratio between the first alloy particle and the second metal particle in the conductive powder, i.e. [(the first alloy particle)/(the second metal particle)], by mass ratio, is preferably 76/24 or more and below 90/10. By setting the mixing ratio within the range, decrease in viscosity of the conductive paste composition is low and there is no worry about leakage of the conductive paste composition from the via hole.

The average particle diameter of the first alloy particle and the second metal particle is preferably 10 μm or less. By setting the diameter of the first alloy particle within the range, filling the conductive paste composition into the via hole becomes easier and the metal tends to be diffused. In addition, by setting the diameter of the second metal particle within the range, effect of adjusting the viscosity of the conductive paste composition when thermally laminating the substrate 100B becomes favorable.

The difference of average particle diameter between the first alloy particle and the second metal particle is preferably 2 μm or less. By equalizing the particle diameter as much as possible, metal diffusion bonding can be easily attained.

The binder component to be used in the invention is a mixture of: a mixture of thermosetting polymerizable monomers; a thermoplastic resin composition; or a mixture of a thermoplastic resin composition and a mixture of thermosetting polymerizable monomers. As the binder component, examples of the thermosetting polymerizable monomer mixture may be a mixture of an alkenyl phenol compound and maleimides. It should be noted that even if the alkenyl phenol compound and/or maleimides are high-molecular compounds, as long as these compounds cure by cross-linking reaction with heating, these compounds can be included in the polymerizable monomer of the invention. Examples of the thermoplastic resin composition include a polyester-based resin.

Examples of the alkenyl phenol compound may be an alkenyl phenol compound having at least two alkenyl group in a molecule, in other words, the alkenyl phenol compound may be a phenol-based compound where a part of hydrogen atom of the aromatic ring is substituted by an alkenyl group. Specifically, examples of the alkenyl phenol compound include a compound where alkenyl groups bind to bisphenol A or phenolic hydroxyl-group-containing biphenyl skeleton. Specific examples thereof include: dialkenyl biphenyldiol compound such as 3,3′-bis(2-propenyl)-4,4′-biphenyldiol, 3,3′-bis(2-propenyl)-2,2′-biphenyldiol, 3,3′-bis(2-methyl-2-propenyl)-4,4′-biphenyldiol, 3,3′-bis(2-methyl-2-propenyl)-2,2′-biphenyldiol; and dialkenyl bisphenol compound such as 2,2-bis[4-hydroxy-3-(2-propenyl)phenyl]propane, 2,2-bis[4-hydroxy-3-(2-methyl-2-propenyl)phenyl]propane (hereinafter, refer to as “dimethallyl bisphenol A”.). Among them, in view of low material cost and capability of stable supply, as an alkenyl phenol compound, dimethallyl bisphenol A is preferably used. The structure of dimethallyl bisphenol A is shown by Formula 1, as follows.

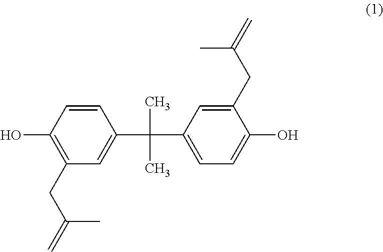

Examples of maleimides may be a maleimide compound having at least two maleimide-groups in the molecule. Specific examples thereof include: bismaleimides such as bis(4-maleimidephenyl)methane; trismaleimides such as tris(4-maleimidephenyl)methane; tetrakis-maleimides such as bis(3,4-dimaleimidephenyl)methane; and polymaleimides such as poly(4-maleimidestyrene). Among them, as the maleimides, in view of low cost and capability of stable supply, bis(4-maleimidephenyl)methane is preferably used. The structure of bis(4-maleimidephenyl)methane is shown by Formula 2, as follows.

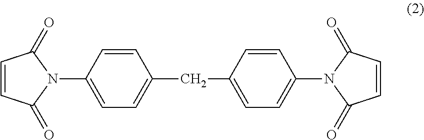

In the binder component, the mixing ratio between the alkenyl phenol compound and the maleimides, i.e. [(alkenyl phenol compound)/(maleimides)], by mole ratio, is preferably 30/70 or more and below 70/30. If dosage of either one of the binder component exceeds the above range, the resin to be produced becomes brittle; thereby adhesiveness between the conductive paste composition and the conductive pattern 20 decreases.

Curing reaction of the binder component will be described as follows. The alkenyl group in an alkenyl phenol compound alternately copolymerizes and/or performs addition reaction with an ethylene-type unsaturated group of a maleimide compound; the phenolic-hydroxyl group also performs addition reaction with an ethylene-type unsaturated group of the maleimide group. Hereinafter, the curing mechanism of the dimethallyl bisphenol A and bis(4-maleimide phenyl)methane exemplified as the binder component will be described. First of all, at a phase of heating at a temperature between 120-180° C., a linear polymer of Formula 3 can be obtained.

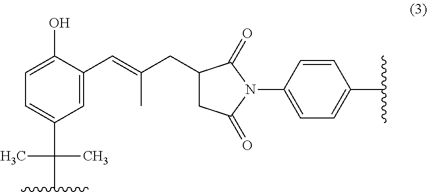

When further heating to 200° C. or more, for example, a polymer of Formula 4 having a 3D cross-linking structure can be obtained.

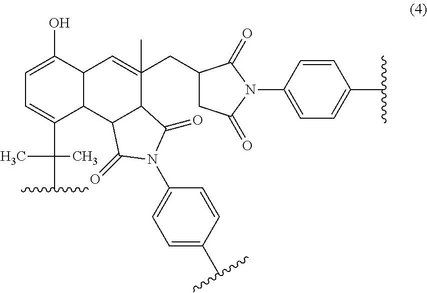

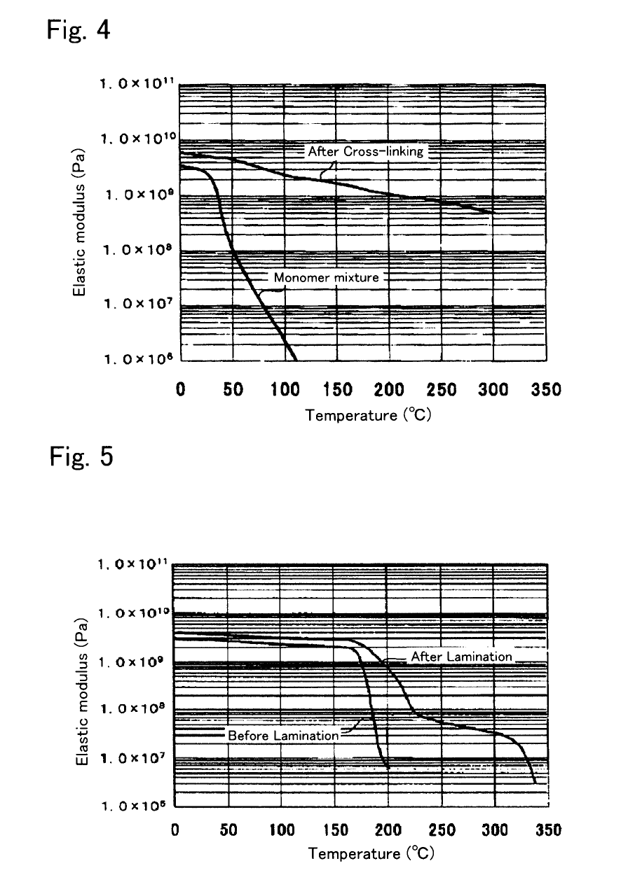

In the present invention, the curing by 3D cross-linking of these binder components promote the solder component to diffuse toward the second metal particle and/or a metal forming the conductive pattern portion; whereby, presumably, well-diffused metal diffusion bonding can be formed. As it were, when the binder component cures, the first alloy particle and the second metal particle in the via hole are under pressure; therefore, it is assumed that the solder component is promoted to diffuse toward metal particle and the metal forming the conductive pattern 20. FIG. 4 is a graph showing a development of elastic modulus of a binder component by temperature. Elastic modulus of the monomer mixture decreases in proportion to the temperature increase. However, since the linear polymer as shown in Formula 3 is formed in a temperature range of 120-180° C., the elastic modulus is suddenly raised (shifting the graph of “monomer mixture” to “after cross-linking” in FIG. 4). Thereafter, linear polymer seems to change into the polymer having a 3D cross-linking structure at a temperature of 200° C. or more. The elastic modulus of graph “after cross-linking” tends to be smaller in proportion to the temperature increase. However, even at a high temperature region, the binder component does not meltdown but does keep a constant elastic modulus.

As above, when the non-lead solder particle melted at a temperature of 130-260° C., the binder component performs curing reaction; thereby it keeps a constant elastic modulus. When the binder cures, pressure is given to the melted non-lead solder particle thereby it is assumed that metal diffusion bonding is attained in the conductive paste composition. So, the multilayer wiring substrate 200 using such a conductive paste composition exhibits extremely small resistance value of the via hole; hence, the thermal resistance under moisture absorption, the connection reliability, and the bonding strength of conductors presumably becomes excellent.

From these aspects, the binder component must be cured at a phase of melting solder particles, when the melting point of the non-lead solder particle is included within the curing temperature range of the binder component, the metal diffusion can be promoted; there is no worry of protrusion of molten solder component from the via hole, thus it is preferable.

As described above, the conductive paste composition contains the conductive powder and the binder component; the mixing ratio of the conductive powder and the binder component, i.e. [(conductive powder)/(binder component)], by mass ratio, is preferably 90/10 or more and below 98/2. By setting the lower limit within the range, increase of electrical resistance value of the conductive paste filled in the via hole can be inhibited; while, by setting the upper limit within the range, it is possible to inhibit deterioration of workability for filling the conductive paste composition into the via hole by printing process and possible to inhibit deterioration of bonding strength between the conductive paste composition and the conductive pattern 20.

(Method for Producing the Wiring Substrate 100a)

The method for producing the wiring substrate 100a is schematically shown in FIG. 2(a). First of all, the insulating base material 10 is formed by the above-described method, such as extrusion casting using T-die. The copper foil 22 is adhered to the insulating base material 10 by thermocompression bonding and then via holes 30 are formed using e.g. laser or mechanical drill. After that, a resist is formed on the surface of the copper foil 22 and the copper foil is etched by a conventional method to form a conductive pattern 20. Later, by a conventional printing method such as screen printing, the conductive paste composition is filled in the via holes 30 to form interlayer wirings. It should be noted that after forming the conductive pattern 20, the interlayer wiring can be formed by copper plating in the via holes 30. Moreover, the conductive pattern 20 may be obtained by adhering the copper foil 22 simultaneously with the film extrusion; it may also be obtained by forming a resist pattern on the insulating base material 10 followed by plating. The order of each steps of the method is not particularly limited. While, in the fabrication method, the predetermined conductive patterns 20 and via holes 30 are formed on/in the insulating base material 10; further, the predetermined conductive patterns 20 may be formed on the insulating base material 10 in advance, and then, after forming a multilayer substrate, the via holes 30 may be formed.

<Wiring Substrate 100a>

Hereinafter, structural members of the wiring substrate 100A will be described. The wiring substrate 100A is the one where predetermined conductive patterns and interlayer wirings are formed on an insulating base material 11 obtained by forming a cavity hole 15 in the insulating base material 10. The wiring substrate 100A is a layer used as the wiring substrate 2 to be arranged at an upper side to the wiring substrate 1 (100a) arranged along the bottom face of the cavity portion when built up into a multilayer wiring substrate; a plurality of the wiring substrates 100A can be laminated. When laminating a plurality of the wiring substrates, at least one layer out of the plurality of the laminated wiring substrates must be the wiring substrate 100A.

### (Method for Producing the Wiring Substrate 100A)

The method for producing the wiring substrate 100A is schematically shown in FIG. 2(b). By forming the cavity hole 15 in the wiring substrate 100a obtained by the above method, a wiring substrate 100A can be obtained.

### (Cavity Hole 15)

The cavity hole 15 is formed in a manner to penetrate the insulating base material 10 in the thickness direction to correspond to the position for mounting the LED element 240. The size and shape of the cavity hole 15 are not particularly limited, these are determined depending on, for example, the size and shape of LED elements 240 to be mounted. With regard to the multilayer wiring substrate 200 shown in FIG. 1(a), each of the plurality of the wiring substrates 100A laminated at the upper side has a cavity hole 15 having the same shape and the same size. Because of this, a cavity portion 220 in a form of rectangular solid is formed in the wiring substrate 200.

As shown in FIG. 2(b), after forming the base material 10, a cavity hole 15 is formed in the base material 10. In general, the cavity hole 15 is formed, for example, by punching out a predetermined shape using Thomson die cutter or by cutting using laser.

Thereafter, a copper foil 22 is adhered by thermocompression bonding to the base material 11 having the cavity hole 15, and then, conductive pattern 20 and via holes 30 are formed to produce the wiring substrate 100A. Alternatively, after adhering the copper foil 22 on the insulating base material 10, the cavity hole 15 can be formed in the same manner as the above method. Accordingly, the wiring substrate 100A can be produced.

Moreover, in the multilayer wiring substrate 200A shown in FIG. 1(b), each of the plurality of wiring substrates 100A laminated at the upper side has a cavity hole 15 of different size from each other. In the plurality of the wiring substrates 100A laminated at the upper side, the upper wiring substrate 100A has a bigger cavity hole 15. Accordingly, the laminated wiring substrate 200A has a cavity portion 220 having a staircase pattern side view.

<Wiring Substrate 100B>

Hereinafter, each structural member of the wiring substrate 100B will be described. The wiring substrate 100B is a substrate where predetermined conductive patterns and interlayer wirings are formed on/in the insulating base material 10a containing a thermoplastic resin composition as a main component. Although the wiring substrate 100B is a layer used as a wiring substrate 3 to be arranged at a lower side of the wiring substrate 1 arranged along the bottom face of the cavity portion of a multilayer wiring substrate, depending on the position of the wiring substrate 100a and wiring substrate 100A, it can be used as the wiring substrate 1 or the wiring substrate 2 arranged at the upper side of the wiring substrate 1. When arranging the wiring substrate 100B at the upper side of the multilayer wiring substrate, a cavity hole 15 may be formed in the same manner as that of the wiring substrate 100A.

(Insulating Base Material 10a)

The thermoplastic resin composition constituting the insulating base material 10a is the same one as that of the above-described insulating base material 10.

The thermoplastic resin composition constituting the insulating base material 10a may contain an inorganic filler; the inorganic filler is not particularly limited, it may be the same one as those of the above-described insulating base material 10.

The additive amount of the inorganic filler, based on 100 parts by mass of the thermoplastic resin composition, is preferably 20 parts by mass or more and 50 parts by mass or less. When the additive amount of the inorganic filler is excessive, mal-diffusion of the inorganic filler occurs, which tends to cause variation of linear expansion coefficient and decrease of strength. On the other hand, when the additive amount of the inorganic filler is too small, the effect to improve dimensional stability by decreasing the linear expansion coefficient becomes less; during the reflow process, internal stress attributed to the difference of the linear expansion coefficient of the insulating base material 10a from that of the conductive pattern 20 is caused; whereby warpage and twist occur in the substrate.

In addition, the thermoplastic resin composition constituting the insulating base material 10a may contain other resins and/or various additives other than the inorganic filler within the range which does not undermine the property. Examples of these additives may be the above-described additives; the method for adding the various additives including these inorganic fillers may be a known method, specifically, the above-described method may be exemplified.

The insulating base material 10a can be produced in the same manner as the above-described method for producing the insulating base material 10. The conductive pattern 20 and via hole 30 can also be formed in the same manner as described in the method for producing the insulating base material 10.

### (Method for Producing the Wiring Substrate 100B)

The wiring substrate 100B is produced in the same manner as the method for producing the wiring substrate 100a except for the point using an insulating base material 10a which mainly contains a thermoplastic resin composition as a main component as the insulating base material. Specifically, the insulating base material 10a containing a thermoplastic resin composition as the main component is formed by the above-described method, for example, by extrusion casting using T-die. Then, a copper foil 22 is adhered to the insulating base material 10a by thermocompression bonding and the via holes are formed by using e.g. laser or mechanical drill. Thereafter, by the conventional method of forming a resist on the surface of the copper foil 22 and etching thereof, the conductive pattern 20 is formed. Alternatively, the conductive pattern 20 may be formed first, and then copper plating may be applied to the via holes 30 to form an interlayer wiring. Further, adhesion of the copper foil 22 may be carried out simultaneously with film forming by extrusion; and a resist pattern may be formed on the insulating base material 10a and then the conductive pattern 20 maybe formed by plating method. The order of each step of the above-methods is not particularly limited. While, in the above method, predetermined conductive patterns 20 and via holes 30 are formed on/in the insulating base material 10a; further, alternatively, predetermined conductive patterns 20 may be formed on the insulating base material 10a first, and then the via holes 30 may be formed after building up a multilayer substrate.

(Behavior of the Elastic Modulus of the Insulating Base Material with Respect to the Temperature)

The behavior of the elastic modulus of the insulating base material with respect to the temperature will be described. FIG. 5 shows a behavior of the elastic modulus of the insulating base material with respect to the temperature in a case of using a composition of crystalline thermoplastic resin as a thermoplastic resin composition having a crystal melting peak temperature of 260° C. or more, wherein the crystalline thermoplastic resin is a mixed composition of polyether ether ketone and amorphous polyetherimide resin.

In FIG. 5, the term “Before Lamination” indicates a graph showing elastic modulus with respect to the temperature of the insulating base material before lamination to form a multilayer wiring substrate; while, the term “After Lamination” indicates a graph showing elastic modulus with respect to the temperature of the insulating base material after forming the multilayer wiring substrate 200 by heating and pressurization under predetermined conditions. In a state before lamination, as above, the insulating base material is processed into an amorphous film by rapid cooling. Therefore, the elastic modulus sufficiently decreases at a relatively low temperature, i.e. around 200° C. Because of this, the insulating base material before lamination can be thermally formed and thermally adhered at a relatively low temperature.

The insulating base material in a form of amorphous film changes into a crystalline form by heating and pressurization under predetermined conditions at a time of producing the multilayer wiring substrate 200. With this change, the elastic modulus of the insulating base material significantly changes and shows the behavior as indicated by the graph of “After Lamination” in FIG. 5. Because of this, by attaining effect of promoting the below-described metal diffusion bonding, it is presumably possible to make the resistance value of the via holes of the multilayer wiring substrate 200 extremely small and also possible to make the multilayer wiring substrate 200 exhibit excellent thermal resistance under moisture absorption, connection reliability, and bonding strength of conductor.

Next, mechanism for promoting metal diffusion bonding will be described. Here, the relation between the non-lead solder particle in the conductive paste composition and the insulating base material is important, and the storage elastic modulus of the resin composition at the melting point of the non-lead solder particle is preferably 10 MPa or more and below 5 GPa. In a case of using a mixed composition of a polyether ether ketone and an amorphous polyetherimide as a thermoplastic resin composition for forming the insulating base material and as a preferable mode, as shown in FIG. 5, storage elastic modulus of the thermoplastic resin composition at a melting point of the non-lead solder particle within the range of 130° C. or more and below 260° C. is 10 MPa or more and below 5 GPa. It should be noted that the storage elastic modulus of the thermoplastic resin composition is determined by viscoelasticity measuring instrument under conditions at a measurement frequency of 1 Hz and a rate of temperature increase of 3° C./min.

As above, if the thermoplastic resin composition has a storage elastic modulus of 10 MPa or more and below 5 GPa at a melting point of non-lead solder particle, which means that, the thermoplastic resin composition can have a certain flexibility and can maintain a certain elastic modulus without melting at the melting point of non-lead solder particle.

In this way, by giving a certain flexibility to the thermoplastic resin composition at a melting point of the non-lead solder particle, the conductive paste composition and the thermoplastic resin composition can have good affinity with each other; thereby adhesiveness between the conductive paste composition and the insulating base material improves. Moreover, when the thermoplastic resin composition does not melt but does maintain a certain elastic modulus at a melting point of the non-lead solder particle, at a time of laminating the wiring substrates by thermofusion bonding, conductive paste composition can be tightened by the thermoplastic resin composition provided at the side face of the via holes; thereby it becomes possible to pressurize the conductive paste composition. Due to this, it is assumed that the tin component in the non-lead solder particle diffuses into the metal forming the second metal particle and/or the conductive pattern portion and eventually attains metal diffusion bonding.

<Method for Fabricating the Multilayer Wiring Substrate 200, 200A>

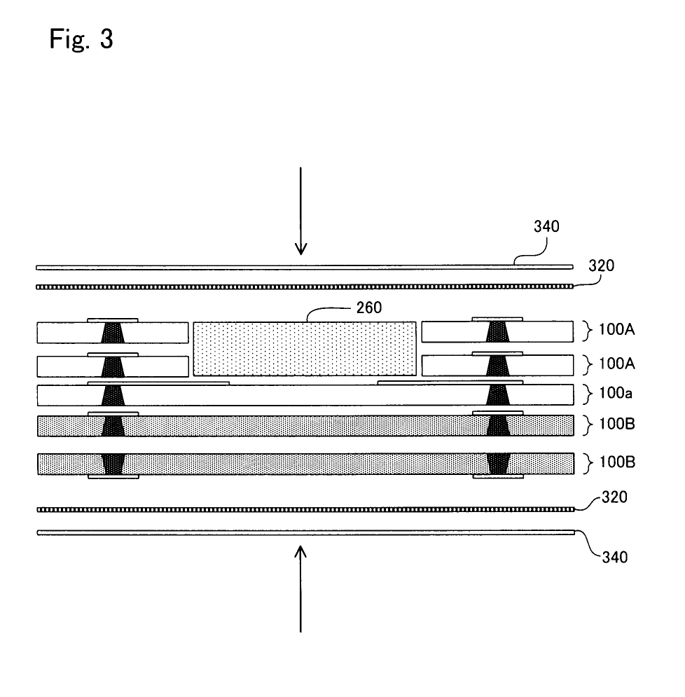

FIG. 3 schematically shows a method for fabricating the multilayer wiring substrate 200 of the invention. In the embodiment shown in FIG. 3, the multilayer wiring substrate comprises: a wiring substrate 100a to be arranged along the bottom face of the cavity portion; a plurality of the wiring substrates 100A arranged at the upper side of the wiring substrate 100a; and a plurality of the wiring substrates 100B arranged at the lower side of the wiring substrate 100a. The multilayer wiring substrate 200 can be fabricated by: vertically placing a plurality of the wiring substrates 100B; laminating a wiring substrate 100a on the upper side of the wiring substrates 100B; laminating a plurality of the wiring substrates 100A, each of which has a cavity hole 15, on the upper side of the wiring substrate 100a being arranged along the bottom face of the cavity portion; and finally treating them by thermocompression bonding. In the fabrication method shown in FIG. 3, the lowermost wiring substrate 100B is placed upside down and laminated so that the wiring pattern 20 is formed at the outer side of the multilayer wiring substrate.

The lamination is preferably carried out under conditions at a temperature of 180° C. or more and below 320° C., a pressure of 3 MPa or more and below 10 MPa, a pressing duration of 10-120 minutes. When laminating under the condition, in a case of using a mixed composition of a polyarylketone resin and an amorphous polyetherimide resin as the insulating base material, the insulating base material processed in an amorphous film changes into a crystalline form by the heat of lamination. Accordingly, the insulating base material attains non-lead solder thermal resistance. Moreover, the conductive paste in the via holes attains metal diffusion bonding; whereby it is possible to make the resistance value of the via holes extremely small and possible to obtain multilayer wiring substrates 200, 200A which exhibit excellent thermal resistance under moisture absorption, connection reliability, and bonding strength of conductors.

Further, when fabricating the multilayer wiring substrates 200, 200A, a spacer 260 is used. The spacer 260 has a substantially the same shape as that of the cavity portion 220; it is used by inserting into the cavity portion 220. When fabricating the multilayer wiring substrate 200A, a spacer 260 having a staircase pattern is used. The spacer 260 can be produced by a material having not only a mold-releasability from the insulating base material 10 and the conductive pattern 20 but also an elastic modulus which can maintain the shape of the cavity portion 220 even at a time of pressure bonding. Examples of the material include a polyimide resin. Alternatively, a metal spacer can be used; a metal die having a bulging shape corresponding to the shape of cavity may also be used.

The thermocompression bonding when fabricating the multilayer wiring substrates 200, 200A is carried out by pressing from the top side and the bottom side of the multi-laminated wiring substrate (as from in FIG. 3) using pressure jigs of a press machine. Between the pressure jigs and the wiring substrate, a mold release film 320 and a stainless-steel sheet 340 are sandwiched. The mold release film 320 is used to secure mold releasability when taking the multilayer wiring substrates 200, 200A out from the press machine after thermocompression bonding. As the mold release film 320, for example, a polyimide film is used. On the other hand, the stainless-steel sheet 340 is used for giving pressure uniformly.

When fabricating the multilayer wiring substrates 200, 200A, a cushioned mold release film may also be used. The material constituting the cushioned mold release film is not specifically limited; a resin of no leaking at a lamination temperature range may be preferably used. Examples of the material include: polyethylene (PE), polypropylene (PP), polymethyl pentene (TPX: trade mark of Mitsui Chemicals, Inc.), syndiotactic polystyrene (SPS), silicon-based resin, fluorine-based resin, and polyimide (PI) resin. The material may have a monolayer structure or have a multilayer structure where a mold-releasable resin is laminated on the surface layer.

Still further, when fabricating multilayer wiring substrates 200, 200A, a plurality of substrates each having a plurality of the wiring substrates 100B in the same plane are laminated, then, a wiring substrate 100a and/or a plurality of wiring substrates each having a plurality of the wiring substrate 100A in the same plane are laminated on the wiring substrates 100B; thereafter, these laminated layers are thermally compressed for bonding. Finally, the obtained multicalyer wiring substrate is cut into pieces of the multilayer wiring substrates 200, 200A. Accordingly, a plurality of the multilayer wiring substrates 200, 200A can be obtained at the same time.

The multilayer wiring substrates 200, 200A of the invention can be used such that the LED elements 240 are mounted on the bottom of its cavity portion 220. The state where the LED elements 240 are mounted is shown in FIG. 1(c) and FIG. 1(d). The embodiment shown in FIG. 1(c) is a mode where LED elements 240 are mounted on the bottom face of the cavity portion 220 and the LED elements 240 are connected with the conductive pattern 20 on the side surface of the cavity portion by bonding wires. In this way, the multilayer wiring substrate 200A of the invention may have a cavity portion 220 having a complex shape such as a staircase form; whereby the LED elements 240 can be mounted in various modes.

On the other hand, the embodiment shown in FIG. 1(d) is a mode where two LED elements 240 are mounted in parallel on the bottom face of the cavity portion 220. In the embodiment, the LED elements 240 are mounted in the cavity portion 220; the LED element 240 and the multilayer wiring substrate 200 are electrically connected by bonding wires. As above, in the multilayer wiring substrate 200 of the invention, the method for mounting LED elements 240 can be realized in various patterns.

To correspond to these methods, position of the via holes 30 can be freely adjusted.

<Multilayer Wiring Substrate 200C, 200D>

The multilayer wiring substrates 200C, 200D of the invention is the one obtained by laminating a plurality of wiring substrates, wherein the multilayer wiring substrate comprises: a wiring substrate 1 being arranged at least along the bottom face of the cavity portion; and a wiring substrate 2 being arranged at the upper layer side of the wiring substrate 1, the wiring substrate 1 and/or the wiring substrate 2 respectively comprise: an insulating base material 10 which comprises an inorganic filler-containing thermoplastic resin composition as a main component and which has an average reflectance of 70% or more in a wavelength range of 400-800 nm and a decreasing rate in reflectance of 10% or less in a wavelength range of 470 nm after thermal treatment at 200° C. for 4 hours; and an adhesive layer 40 containing a thermosetting resin composition as a main component arranged at least one surface of the insulating base material 10 (hereinafter, it may be referred to as the “insulating base material 12”.), further, the wiring substrate 2 being made of an insulating base material (not shown) in which cavity hole (s) 15 is/are provided. Predetermined conductive pattern 22 and via holes 30 to be the interlayer wirings are formed on these insulating base materials, for providing a wiring substrate 100c and a wiring substrate 100C, and finally these are laminated into a multilayer form; in this way, the LED element can be mounted thereon.

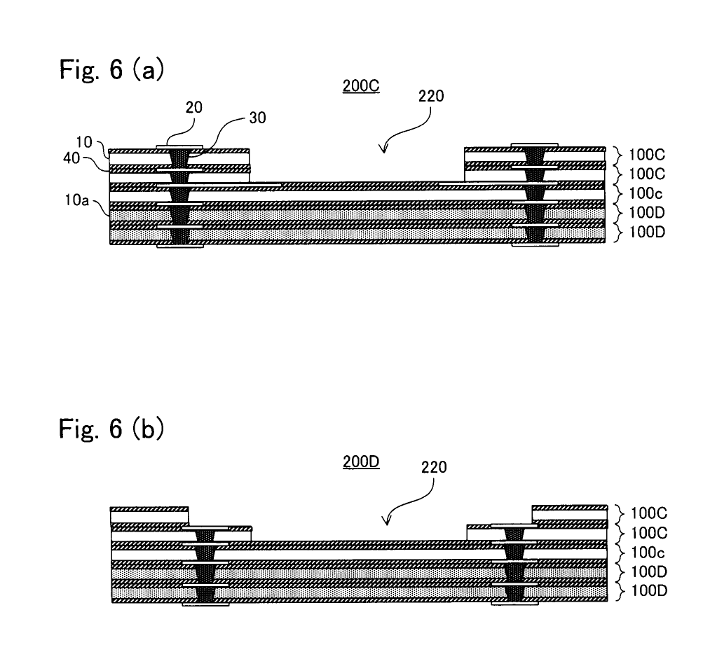

FIGS. 6(a) and 6(b) schematically show the multilayer wiring substrates 200C, 200D, respectively. In the embodiment of FIG. 6(a), the wiring substrate 1 arranged along the bottom face of the cavity portion is composed of the wiring substrate 100c and all the wiring substrates 2 arranged at the upper side are individually composed of the wiring substrate 100C. When mounting LED elements in the cavity portion, by having such a structure, the function as a reflector can be significantly attained; thus it is preferable. Moreover, in the structure, although the wiring substrate 100D is arranged underneath the wiring substrate 1, not only this structure but also a structure where the wiring substrate 100d having a cavity hole is arranged at the upper side of the wiring substrate 100D can be available. It should be noted that the wiring substrate 100D comprises an insulating base material 10a containing a thermoplastic resin composition as a main component; and an adhesive layer 40 which contains a thermosetting resin composition as a main component and which is arranged at least on one surface of the insulating base material 10a. The structure of the wiring substrate may be various.

<Wiring Substrate 100c>

The wiring substrate 100c comprises: an insulating base material 10 which contains an inorganic filler-containing thermoplastic resin composition as a main component and has an average reflectance of 70% or more in a wavelength range of 400-800 nm and a decreasing rate in reflectance of 10% or less in a wavelength range of 470 nm after thermal treatment at 200° C. for 4 hours; an adhesive layer 40 which contains a thermosetting resin composition as a main component and which is provided at least on one surface of the insulating base material 10; a predetermined conductive pattern; and a predetermined interlayer wiring. In the multilayer wiring substrate, for example, the wiring substrate 100c may be used as the wiring substrate 1 being arranged along the bottom face of the cavity portion or a wiring substrate being arranged at the lower side of the wiring substrate 1 arranged along the bottom face of the cavity portion.

### (Adhesive Layer)

On the wiring substrate 100c, an adhesive layer 40 is formed to attain adhesiveness between the neighboring layers. The adhesive layer 40 is formed on at least one surface of the insulating base material 10. When the insulating base material 10 is formed on at least one surface of the adhesive layer 40, these layers can be laminated by thermocompression bonding; as shown in the drawings, the adhesive layer 40 may be formed on both sides of the insulating base material 10.

As a material for constituting the thermosetting resin composition for forming the adhesive layer 40 is not particularly limited as long as it thermally sets at a lamination temperature range of 180° C. or more and below 320° C. and shows non-lead solder thermal resistance; for example, there may be an epoxy-based resin and a polyamide-based resin. Among them, in view of e.g. thermal resistance and electric characteristics, a mixture of an alkenyl phenol compound and a maleimides, as binder components for constituting the above-described conductive paste composition, is particularly preferably used. Into the mixture, within the range which does not undermine the properties, other thermosetting resins, thermoplastic resins, and inorganic fillers, and various additives such as stabilizer, ultraviolet absorber, light stabilizer, nucleating agent, coloring agent, lubricant, flame retardant, film-forming aid, radical polymerization initiator, epoxy group reaction catalyst, thixotropic agent, and silane coupling agent can be added.

The thickness of the adhesive layer 40 to that of the insulating base material 10 is preferably ⅕ or less, more preferably 1/10 or less, and further more preferably 1/20 or less. The thickness of the adhesive layer 40 is preferably 30 μm or less, more preferably 20 μm or less, and further more preferably 10 μm or less. If the thickness of the adhesive layer 40 is too large, the resin may drain into the formed cavity portion 220, which results in the coverage of the conductive pattern 20 or the resin may drain into the via holes 30 at a time of sequential lamination, which inhibits metal diffusion.

<Method for Producing Wiring Substrate 100c>

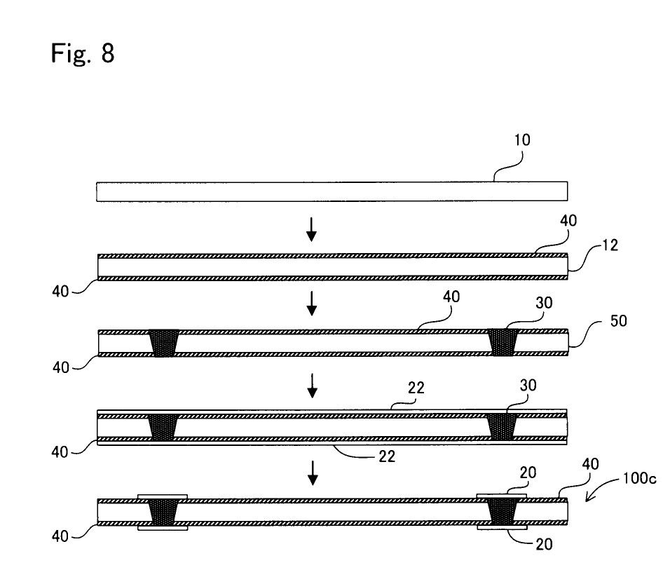

As the method for producing the wiring substrate 100c, first of all, the insulating base material 10 is formed in the same manner as the method for producing the wiring substrate 100a, for example, by extrusion casting using T-die. Then, a solvent containing a thermosetting resin composition is applied on a mold-releasable polyethylene terephthalate (PET) film and solidified by drying in advance to form the adhesive layer 40 on a film having stripping performance. Later, by thermally transferring the adhesive layer 40 on the insulating base material 10 by thermal lamination, the adhesive layer 40 is formed on both sides of the insulating base material 10. Further, the via holes 30 are formed therein using laser or a mechanical drill. Thereafter, by a conventional printing method such as screen printing, a conductive paste composition is filled in the via holes 30 to form interlayer wirings; thus, the insulating base material 50 is obtained (see FIG. 8.).

On both sides of the insulating base material 10 where the adhesive layers 40 are laminated, copper foils 22 are laminated; a resist is formed on the copper foils 22 and then etched by a conventional etching method to form a conductive pattern 20 as an interlayer wiring. Accordingly, a wiring substrate 100c (double-sided substrate) having a conductive pattern 20 on both sides thereof can be formed. Alternatively, by forming via holes, copper plating to form a copper foil 22, and etching it, a conductive pattern 20 can be formed as an interlayer wiring. The order of each step of the production method is not particularly limited. Further, in the production method, although a predetermined conductive pattern 20 and via holes 30 are formed on/in the insulating base material 10, it may be produced by forming a predetermined conductive pattern 20 on the insulating base material 10 in advance, and forming the via holes 30 after building up a multilayer wiring substrate; an insulating base material having the via hole 30 only may be used.

<Wiring Substrate 100C>

The wiring substrate 100C is the one where a predetermined conductive pattern and interlayer wirings are formed on the insulating base material obtained by forming a cavity hole 15 in the insulating base material 12. The cavity hole 15 is formed, after forming the adhesive layer 40 on the insulating base material 10 in the same manner as the forming method of cavity hole in the case of the wiring substrate 100A. Formation of the via hole 30 may be before or after the formation of the cavity hole 15.

<Wiring Substrate 100D>

The wiring substrate 100D is the one comprising: an insulating base material 13 comprising an insulating base material 10a containing a thermoplastic resin composition as a main component; an adhesive layers 40 which contains a thermosetting resin composition as a main component and which is provided on at least one surface of the insulating base material 10a; and a predetermined conductive pattern and interlayer wiring. The insulating base material 10a containing the thermoplastic resin composition as a main component, the conductive pattern 20, and the via hole 30 are substantially the same as those of the above-described wiring substrate 100B; the adhesive layer 40 is substantially the same as that of the above-described wiring substrate 100c.

### (Method for Producing Wiring Substrate 100D)

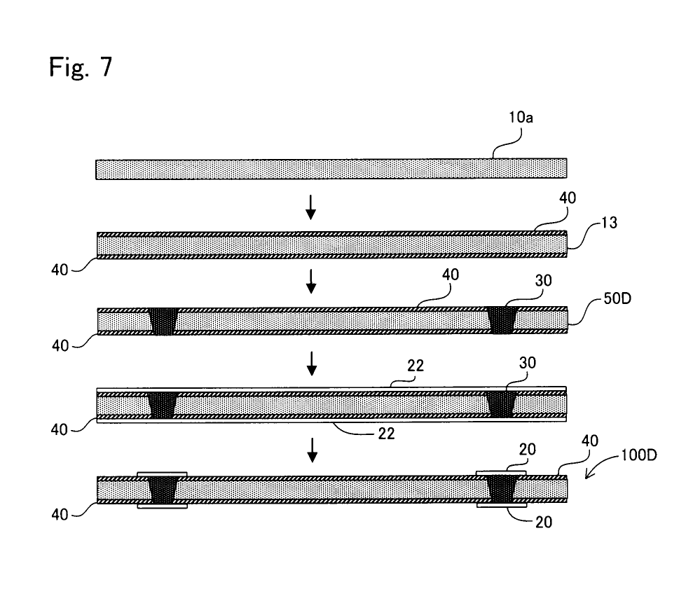

Except for using the insulating base material 10a, the wiring substrate 100D can be produced in the same manner as that of the wiring substrate 100c. The FIG. 7 shows a schematic view illustrating the method for producing the wiring substrate 100D.

### (Insulating Base Material 50C)

The insulating base material 50C is produced by forming a cavity hole 15 in the insulating base material 50 (see FIG. 8.) obtained during the production of the wiring substrate 100c. The cavity hole 15 is formed, after forming the adhesive layer 40 on the insulating base material 10 in the same manner as the forming method of cavity hole in the case of the wiring substrate 100A. The formation of the via holes 30 in the insulating base material 50C may be before and after the formation of the cavity hole 15.

<Method for Fabricating Multilayer Wiring Substrate 200C, 200D>

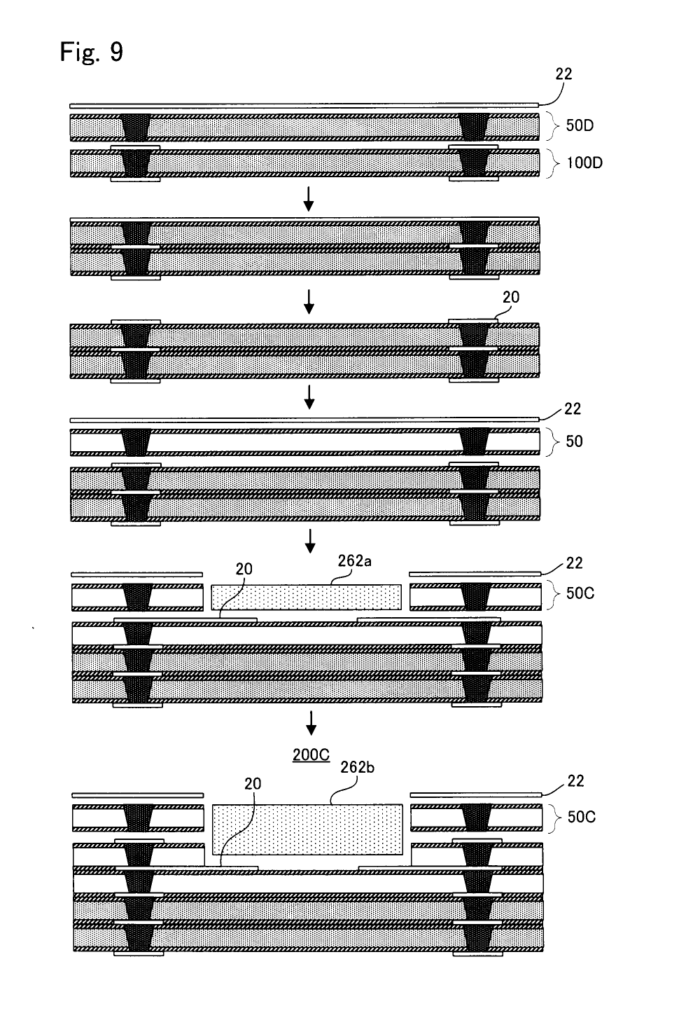

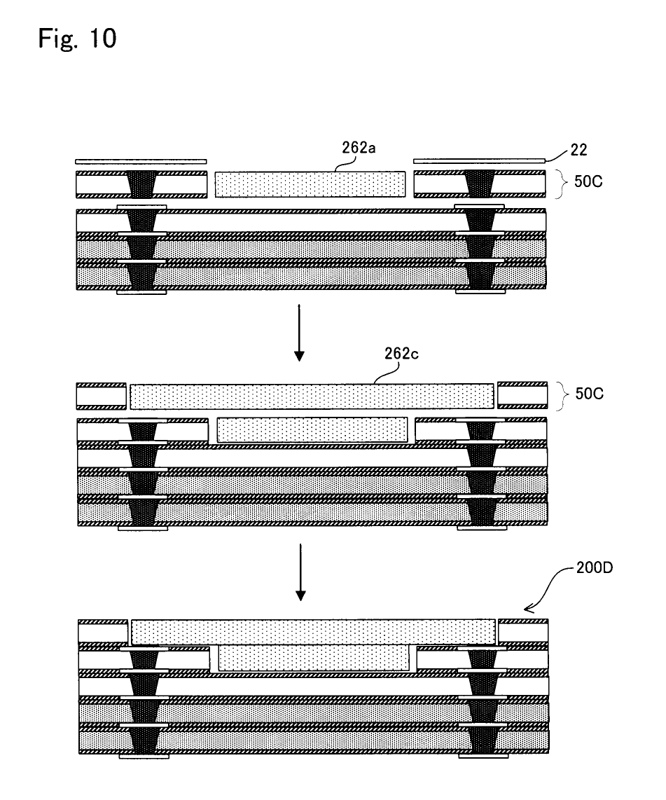

FIGS. 9 and 10 schematically show the method (sequential lamination) for fabricating the multilayer wiring substrates 2000 and 200D of the invention. The lamination method may be carried out by thermocompression bonding; either batch lamination or sequential lamination can be employed. In the case of batch lamination, the multilayer wiring substrates 200C, 200D can be fabricated by superposing the single-sided substrate having a conductive pattern 20 on one side and then carrying out thermocompression bonding in the same manner as that of the multilayer wiring substrate 200, 200A. Hereinafter, with reference to FIGS. 9 and 10, the method for fabricating the multilayer wiring substrates 200C, 200D employing sequential lamination will be described.

FIG. 9 schematically shows the method for fabricating the multilayer wiring substrate 2000. First of all, an insulating base material 50D is superposed on a wiring substrate 100D, and a copper foil 22 is superposed thereon; then, these layers are laminated by thermocompression bonding. By a method such as etching, the copper foil 22 is processed into a wiring pattern 20. The series of operation can be repeated depending on the desired number of the insulating base material 50D to be formed on the wiring substrate 100D.

Later, on the insulating base material 50D, an insulating base material 50 to be located along the bottom face of the cavity portion is superposed, further, a copper foil 22 is superposed thereon; then, these layers are laminated by thermocompression bonding. By a method such as etching, the conductive pattern 20 is formed. Moreover, an insulating base material 50C in which a cavity hole 15 is formed is superposed on the base material 50, and a copper foil 22 is superposed thereon; then, these layers are laminated by thermocompression bonding. By a method such as etching, the copper foil 22 is processed into a conductive pattern 20. The series of operation can be repeated depending on the desired number of the insulating base material 50C to be formed. In the method for fabricating the multilayer wiring substrate 200D shown in FIG. 10, except for the different shape of the spacer to be used, the multilayer wiring substrate 200D is fabricated in the same manner as above. In this way, by sequentially repeating the steps of: laminating insulating base materials 50D, 50, 50C and a copper foil 22 on the wiring substrate 100D by thermocompression bonding; and etching the copper foil, the multilayer wiring substrates 200C and 200D can be fabricated.

The conditions of the sequential lamination in the multilayer wiring substrates 200C, 200D may preferably be at a temperature of 180° C. or more and below 320° C., a pressure of 3 MPa or more and below 10 MPa, a pressing duration of 10-120 minutes. By laminating under the conditions, when the insulating base material is the mixed composition of a polyarylketone resin and an amorphous polyetherimide resin, the insulating base material processed into an amorphous film is changed into the crystallized one by heating at a time of lamination. Because of this, the insulating base material can attain non-lead solder thermal resistance. In addition, by laminating under the conditions, the adhesive layer 40 made of a thermosetting composition cures and non-lead solder thermal resistance is attained. Moreover, metal diffusion bonding of the conductive paste in the via hole 30 can make the resistance value extremely small, so that it is possible to fabricate the multilayer wiring substrates 200C, 200D which exhibit excellent thermal resistance under moisture absorption, connection reliability, and bonding strength of conductors.

When laminating the insulating base material 50C in which a cavity hole 15 has been formed, a spacer having a shape corresponding to the shape of the cavity hole 15 can be used. In FIG. 9, when laminating the first layer of the insulating base material 50C and the copper foil 22, a spacer 262a having a thickness equivalent to sum of the thickness of the insulating base material 50C and the copper foil 22 is used. Later, when laminating the second layer of the insulating base material 50C and the copper foil 22, a spacer 262b twice as thick as the spacer 262a is used. Instead of using one spacer 262b, two spacers 262a may be used.

When fabricating the multilayer wiring substrate 200D shown in FIG. 10, as the size of cavity holes 15 in the first insulating base material 50C and the second insulating base material 50C are different from each other, so that the spacers 262a and 262c having a size corresponding to the size of the cavity holes 15 are used. When laminating the second wiring substrate 50C, instead of using spacers 262a and 262c, a spacer having a staircase pattern can be used. The material of the spacer may be the same as that of the spacer in the multilayer wiring substrates 200, 200A.

In the same manner as the case of multilayer wiring substrates 200, 200A, a mold release film 320 and a stainless steel sheet 340 are used at a time of hot pressing. In the same way, a mold release film showing cushion effect can also be used as a mold release film 320. Further, in the same way, a plurality of the multilayer wiring substrate can be fabricated simultaneously by laminating substrates including a plurality of the wiring substrate in the same plane. In the same manner as the embodiments shown in FIGS. 1(c) and 1(d), the multilayer wiring substrates 200C and 200D can be used for mounting LED elements 240.

<Multilayer Wiring Substrate 200E>

The multilayer wiring substrate 200E of the invention is another embodiment of the multilayer wiring substrate (200, 200A) having a plurality of wiring substrates laminated each other. In the multilayer wiring substrate, a wiring substrate 1 is arranged at least along the bottom face of the cavity portion and a wiring substrate 2 is arranged at an upper layer side of the wiring substrate 1; the wiring substrate 1 and/or the wiring substrate 2 respectively comprise an insulating base material 10 which comprises an inorganic filler-containing thermoplastic resin composition as a main component and which has an average reflectance of 70% or more in a wavelength range of 400-800 nm and a decreasing rate in reflectance of 10% or less in a wavelength range of 470 nm after thermal treatment at 200° C. for 4 hours; and the wiring substrate 2 is made of an insulating base material 11 obtained by forming a cavity hole 15 in the insulating base material 10. Thereafter, predetermined conductive pattern 22 and via holes 30 as an interlayer wiring are formed on/in the insulating base materials 10 and 11 to produce the wiring substrate 100a and wiring substrate 100A, then, these wiring substrates are built up to form a multilayer wiring substrate for mounting LED elements thereon.

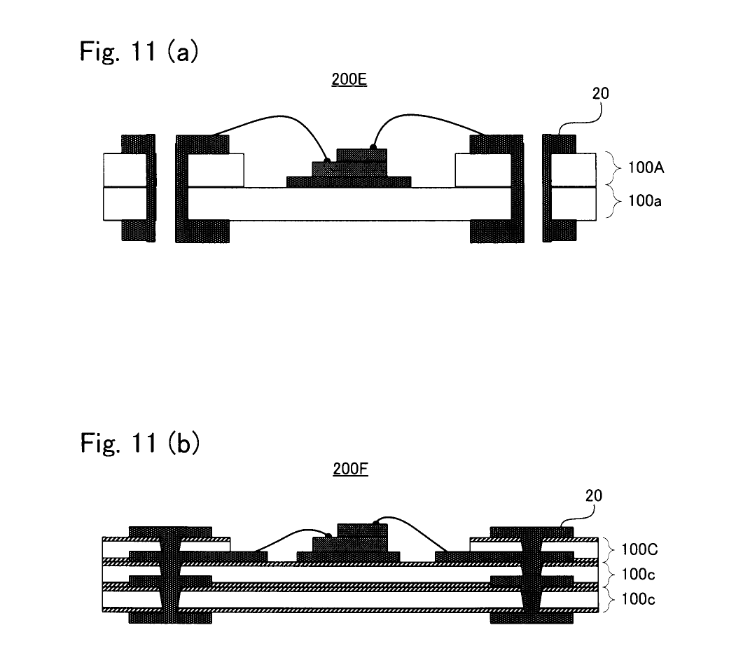

The multilayer wiring substrate 200E of the invention is, as shown in FIG. 11(a), the one where predetermined conductive patterns and via holes as an interlayer wiring (hereinafter, referred to as “through hole”.) are formed on/in the insulating base materials 10 and 11 to form the wiring substrates 100a and wiring substrate 100A, then, these wiring substrates are built up to fabricate a multilayer wiring substrate for mounting LED elements thereon.

<Method for Fabricating the Multilayer Wiring Substrate 200E>

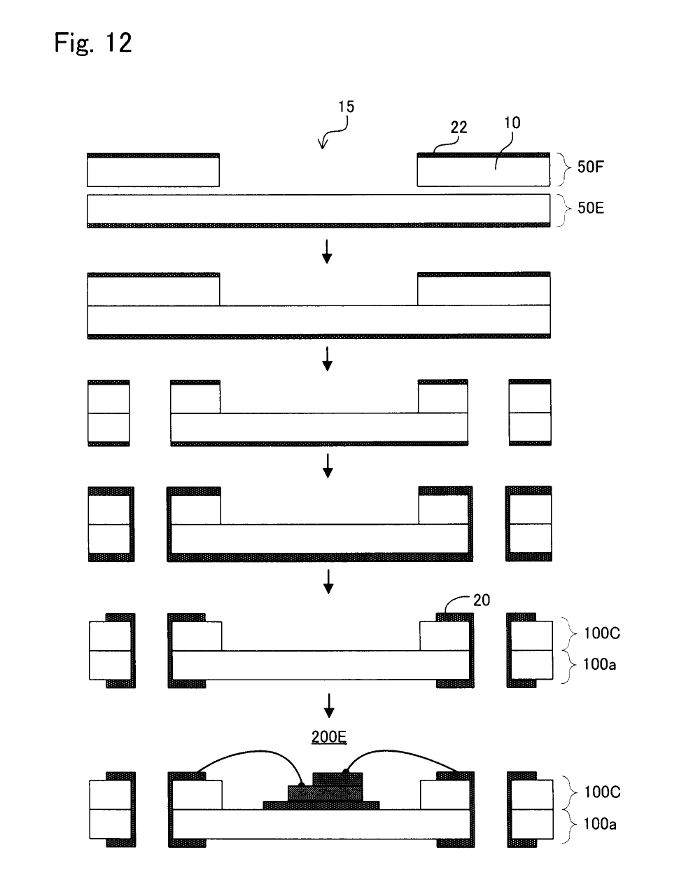

FIG. 12 schematically shows the method for fabricating the multilayer wiring substrate 200E. As shown in FIG. 12, firstly, the insulating base material 10 is produced in accordance with the above method, such as extrusion casting using T-die, and a copper foil 22 is laminated thereon to produce a one-sided copper-laminated insulating base material 50E. In accordance with the above method, a one-sided copper-laminated insulating base material 50F is also produced by forming a cavity hole 15 in the insulating base material 50E. By superposing the insulating base material 50F on the insulating base material 50E and laminating these layers by thermocompression bonding, then, forming through holes using laser or a mechanical drill, and forming conductive patterns and interlayer wirings by photolithographic approach, the multilayer wiring substrate 200E is fabricated.

<Multilayer Wiring Substrate 200F>

The multilayer wiring substrate 200F of the invention is another embodiment of the multilayer wiring substrate (200C, 200D) having a plurality of wiring substrate laminated each other. In the multilayer wiring substrate, a wiring substrate 1 is arranged at least along the bottom face of the cavity portion and a wiring substrate 2 is arranged at an upper layer side of the wiring substrate 1; the wiring substrate 1 and/or the wiring substrate 2 respectively comprise: an insulating base material 10 which comprises an inorganic filler-containing thermoplastic resin composition as a main component and which has an average reflectance of 70% or more in a wavelength range of 400-800 nm and a decreasing rate in reflectance of 10% or less in a wavelength range of 470 nm after thermal treatment at 200° C. for 4 hours, and an adhesive layer 40 which comprises a thermosetting resin composition as a main component and which is provided on at least one side of the insulating base material 10 (hereinafter, it may be referred to as “insulating base material 12”.); further, the wiring substrate 2 is made of an insulating base material 12 where a cavity hole 15 is formed in the insulating base material (not shown). Still further, predetermined conductive patterns 20 and via holes 30 as an interlayer wiring are formed on/in the insulating base material to form the wiring substrate 100c and the wiring substrate 1000, then, these wiring substrates are built up to form a multilayer wiring substrate for mounting LED elements thereon.

<Method for Fabricating Multilayer Wiring Substrate 200F>

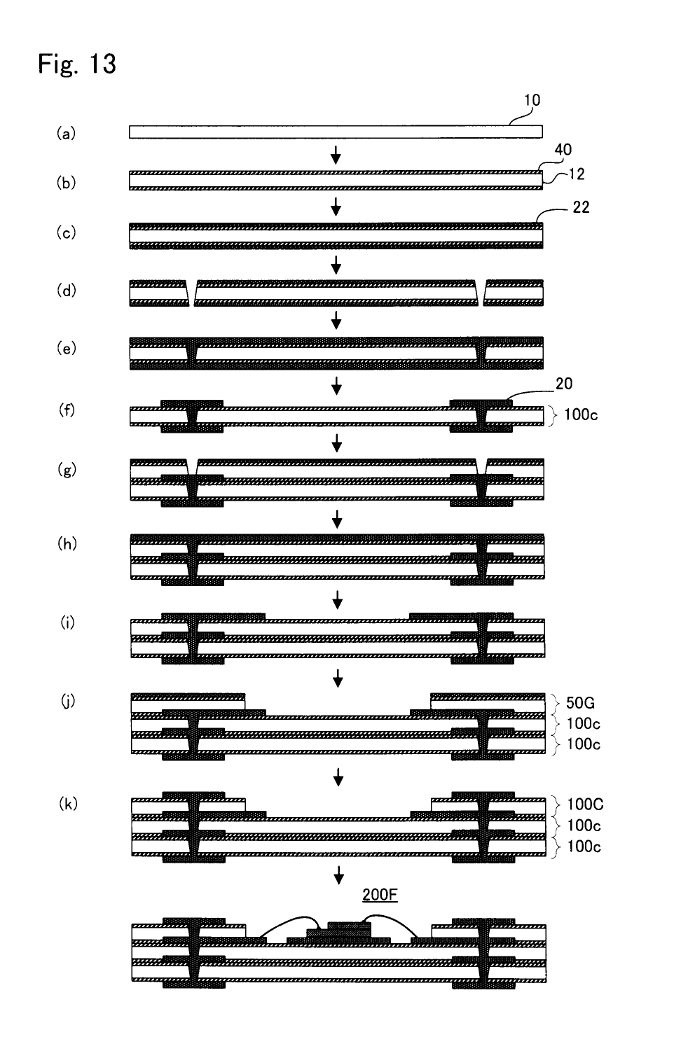

FIG. 13 schematically shows a method for fabricating the multilayer wiring substrate 200F (sequential lamination). As shown in FIG. 13, first of all, the insulating base material 10 is produced in accordance with the above method, such as extrusion casting using T-die (Step (a) of FIG. 13). Then, a thermosetting resin composition-containing solvent is applied on a mold-releasable polyethylene terephthalate (PET) film and solidified by drying in advance to form the adhesive layer 40 on a film having stripping performance. Later, by thermally transferring the adhesive layer 40 onto the insulating base material 10 by thermal lamination, the adhesive layer 40 is formed on both sides of the insulating base material 10 (Step (b) of FIG. 13). A copper foil 22 is superposed on both sides of the insulating base material to which the adhesive layer is laminated, and these layers are treated by thermocompression bonding (Step (c) of FIG. 13). Further, through holes are formed by using, for example, laser or a mechanical drill (Step (d) of FIG. 13). Thereafter, interlayer wirings are formed by, for example, filling and plating (Step (e) of FIG. 13); still further, conductive patterns 20 are formed by photolithographic approach, to obtain the wiring substrate 100c (Step (f) of FIG. 13). These operations may be repeated depending on the number of the wiring substrate 100c to be formed (Steps (g)-(i) of FIG. 13).

In the same manner as the above-described multilayer wiring substrate 200F, the adhesive layer 40 is thermally transferred on both sides of the insulating base material 10 in advance, a copper foil 22 is superposed on one side of the insulating base material on which the adhesive layer 40 is laminated, and these layers are laminated by thermocompression bonding, to obtain an insulating base material 50G. The insulating base material 50G is superposed on the wiring substrate 100c and lamination is carried out by thermocompression bonding (Step (j) of FIG. 13). By the method such as etching, the copper foil 22 can be processed into conductive patterns 20 (Step (k) of FIG. 13). These operations may be repeated depending on the number of the insulating base material 50G to be formed. As above, by sequentially and repeatedly performing the steps of: laminating the insulating base material 50G and the copper foil 22 on the wiring substrate 100c by thermocompression bonding; and etching the copper foil, the multilayer wiring substrate 200F is fabricated.

In this way, the multilayer wiring substrates 200, 200A, 200C, 200D, 200E, and 200F can be designed such that the cavity portion 220 has various shapes. Accordingly, method for mounting LED elements 240 and method of electric connection may be varied.

### Examples

Hereinafter, the present invention will be described in detail based on the Examples; however, the invention is not limited to these Examples.

### Example 1

(Production of the Wiring Substrate 100a)

A thermoplastic resin composition obtained by mixing: to 100 parts by mass of a resin mixture having: 40 mass % of a polyether ether ketone resin (PEEK 450G, Tm=335° C.), and 60 mass % of an amorphous polyetherimide resin (ULTEM 1000) ; 16 parts by mass of titanium oxide (average particle diameter of 0.23 μm, alumina treatment, silane coupling treatment) produced by chlorine method; and 45 parts by mass of a synthetic mica having an average particle diameter of 5 μm and an average aspect ratio of 50, was melt-kneaded, then the melt-kneaded resin composition was extruded into a film having a thickness of 100 μm simultaneously with lamination of a copper foil 22 from one side thereof, to obtain a one-sided copper-laminated insulating base material. Via holes each having a diameter of 100 μm were formed at predetermined positions using laser and a conductive paste composition was filled in the via holes by screen printing. After filling, the resultant sheet was heated at 125° C. for 45 minutes, then, the solvent was volatilized to dry and solidify the conductive paste. Finally, by photolithographic approach, the conductive pattern 20 was formed in the copper foil. By the above method, the wiring substrate 100a having an inter-via distance of 150 μm and an inter-wiring distance of 50 μm was produced.

The conductive paste composition used as above may be prepared by: adding, to 97 parts by mass of conductive powder containing: 76 mass % of an Sn—Ag—Cu alloy particle (average particle diameter of 5.55 μm, melting point of 220° C., composition having: 3.0 mass % of Ag, 0.5 mass % of Cu, and remaining portion of Sn) and 24 mass % of Cu particles (average particle diameter of 5 μm), 3 parts by mass of a polymerizable monomer mixture containing 50 mass % of dimethallyl bisphenol A and 50 mass % of bis (4-maleimide phenyl) methane and 7.2 parts by mass of γ-butyrolactone as a solvent; and then kneading by triple-roll mill.

### (Production of the Wiring Substrate 100A)

A cavity hole 15 was formed in the one-sided copper-laminated insulating base material produced in the production process of the wiring substrate 100a, by punching out a predetermined shape using Thomson die cutter. Via holes are formed in the one-sided copper-laminated insulating base material having the cavity hole 15, in the same manner as the production method of the wiring substrate 100a; then, the conductive paste composition was filled into the via holes and dried for solidification. Later, by photolithographic approach, the copper foil 22 was processed into the conductive pattern 20; thus the wiring substrate 100A was obtained. The conductive paste composition used was substantially the same one used in the production process of the wiring substrate 100a.

### (Production of the Wiring Substrate 100B)

A thermoplastic resin composition obtained by mixing: to 100 parts by mass of a resin mixture having: 40 mass % of a polyether ether ketone resin (PEEK 450G, Tm=335° C.), and 60 mass % of an amorphous polyetherimide resin (ULTEM 1000); and 39 parts by mass of a synthetic mica having an average particle diameter of 5 μm and an average aspect ratio of 50, was melt-kneaded, then the melt-kneaded resin composition was extruded into a film having a thickness of 100 μm simultaneously with lamination of a copper foil 22 from one side thereof, to obtain a one-sided copper-laminated insulating base material. Thereafter, in the same manner as the production process of the wiring substrate 100a, via holes were formed; a conductive paste composition was filled therein and dried for solidification. Then, by photolithographic approach, the copper foil 22 was processed into the conductive pattern 20; thus the wiring substrate 100B was obtained. The conductive paste composition used was substantially the same one as that used in the production process of the wiring substrate 100a.

### (Fabrication of the Multilayer Wiring Substrate 200)

Two wiring substrates 100A, one wiring substrate 100a, and two wiring substrate 100B thus obtained were prepared and laminated each other so that the two wiring substrate 100B were laminated at a lower part, the one wiring substrate 100a was laminated on the wiring substrate 100B along the bottom face of the cavity portion and the two wiring substrate 100A were laminated on the wiring substrate 100a. When laminating each wiring substrate, lamination was carried out so that the positions of the via holes 30 and the cavity hole of each layer align. Then, each layer was laminated by arranging in the cavity portion 220 a polyimide resin-made spacer 260 having the same shape and thickness as those of the cavity portion 220; and vacuum pressing. The pressing conditions are at 230° C. and at a pressure of 5 MPa for 30 minutes. Accordingly, the five-layered multilayer wiring substrate 200 having the cavity portion 220 was fabricated.

### Example 2

### (Fabrication of the Multilayer Wiring Substrate 200A)

In the same manner as Example 1, the wiring substrate 100a and the wiring substrate (s) 100A were produced. With respect to the wiring substrates 100A, the first wiring substrate has a cavity hole 15 having the same size as that of Example 1 and the second one has a cavity hole 15 having slightly larger size. Thereafter, the two wiring substrates 100B were laminated at a lower side, the one wiring substrate 100a was laminated on the wiring substrates 100B along the bottom face of the cavity portion, the first wiring substrate 100A having the cavity hole 15 having the same size as that of Example 1 was laminated thereon, and finally, the second wiring substrate 100A having the cavity hole 15 having slightly larger size than that of Example 1 was laminated. By arranging a staircase-pattern polyimide resin-made spacer 260 having the same shape and thickness in the space to be the cavity portion 220, and by thermocompression bonding in the same manner as Example 1, a five-layered multilayer wiring substrate 200A having a staircase pattern cavity portion 220 was fabricated.

### Example 3

### (Production of the Wiring Substrate 100D)

A thermoplastic resin composition obtained by mixing: to 100 parts by mass of a resin mixture having: 65 mass % of a polyether ether ketone resin (PEEK 450G, Tm=335° C.), and 35 mass % of an amorphous polyetherimide resin (ULTEM 1000); 39 parts by mass of a synthetic mica having an average particle diameter of 5 μm and an average aspect ratio of 50, was melt-kneaded; and then the melt-kneaded resin composition was extruded into a film (i.e. insulating base material) having a thickness of 100 μm. After giving corona discharge treatment to both sides of the obtained film, a solution containing a polymerizable monomer prepared by mixing 50 mass % of dimethallyl bisphenol A and 50 mass % of bis(4-maleimidephenyl)methane was applied on a mold-releasable PET film and solidified by drying to form a 5 μm thick adhesive layer. Then, the adhesive layer was thermally transferred onto both surfaces of the insulating base material.

Then, via holes having a diameter of 100 μm were formed at desired positions by using laser. A conductive paste composition was filled in the via holes by screen printing. After filling, the resultant sheet was heated at 125° C. for 45 minutes, then, the solvent was volatilized and the conductive paste was solidified by drying. Accordingly, the insulating base material 50D was produced. Later, by laminating a 12 μm thick copper foil on both sides of the insulating base material under conditions at 230° C. and at a pressure of 5 MPa for 30 minutes and forming a conductive pattern 20 from the copper foil by photolithographic approach, the wiring substrate 100D was obtained. The conductive paste composition used was the same as the one used in Example 1.

### (Production of the Insulating Base Material 50)

A thermoplastic resin composition obtained by mixing: to 100 parts by mass of a resin mixture having: 65 mass % of a polyether ether ketone resin (PEEK 450G, Tm=335° C.), and 35 mass % of an amorphous polyetherimide resin (ULTEM 1000); 16 parts by mass of titanium oxide (average particle diameter of 0.23 μm, alumina treatment, silane coupling treatment) produced by chlorine method; 45 parts by mass of a synthetic mica having an average particle diameter of 5 μm and an average aspect ratio of 50, was melt-kneaded, and then the melt-kneaded resin composition was extruded into a film having a thickness of 100 μm. After giving corona discharge treatment to both sides of the obtained film, a solution containing a polymerizable monomer prepared by mixing 50 mass % of dimethallyl bisphenol A and 50 mass % of bis(4-maleimidephenyl)methane was applied on a mold-releasable PET film and solidified by drying to form a 5 μm thick adhesive layer. Then, the adhesive layer was thermally transferred onto both surfaces of the insulating base material.

Then, via holes having a diameter of 100 μm were formed at desired positions by using laser; and a conductive paste composition was filled in the via holes by screen printing. After filling, the resultant sheet was heated at 125° C. for 45 minutes, then, the solvent was volatilized and the conductive paste was solidified by drying. In this way, the insulating base material 50 was produced. The conductive paste composition used was the same as the one used in Example 1.

### (Production of the Insulating Base Material 50C)

In the same manner as the above-described production of the wiring substrate 100c, adhesive layers were formed on both sides of the insulating base material; then, a cavity hole 15 was formed by punching out a predetermined shape using Thomson die cutter. In the same manner as the production of the wiring substrate 100c, via holes were formed in the insulating base material having a cavity hole 15; a conductive paste composition was filled therein and solidified by drying to obtain the insulating base material 50C.

### (Production of the Multilayer Wiring Substrate 200C)

The insulating base material 50D and the copper foil 22 were superposed on the obtained wiring substrate 100D and laminated by thermocompression bonding, then, the copper foil 22 was processed into a conductive pattern by photolithographic approach; further, another insulating base material 50 and another copper foil 22 were superposed thereon and laminated by thermocompression bonding, then, the copper foil 22 was processed into a conductive pattern by photolithographic approach. Still further, the steps of superposing the insulating base material 50C and the copper foil 22 in the order mentioned and laminating by thermocompression bonding, and then, processing the copper foil 22 into a conductive pattern by photolithographic approach were repeated twice. When laminating the insulating base material 50D, 50C, and 50, positions of the via holes 30 and cavity hole of each insulating base material were aligned. Moreover, when laminating the insulating base material 50C, a polyimide resin-made spacer was used; in the cases of arranging the first insulating base material 50C and the second insulating base material 50C, thickness of the spacers were varied and those spacers were laminated. Pressing conditions of the sequential lamination were at 230° C., at a pressure of 5 MPa for 30 minutes. Thus, the five-layered multilayer wiring substrate 200C having a cavity portion was fabricated.

### Example 4

### (Fabrication of the Multilayer Wiring Substrate 200D)

In the same manner as Example 3, the wiring substrate 100D and the insulating base materials 50D and 50 were produced. With respect to the insulating base material 50C, the first one has a cavity hole 15 having the same size as that of Example 3, the second one has a cavity hole having slightly bigger size than that of Example 3. The insulating base material 50D and the copper foil 22 were superposed on the wiring substrate 100D and laminated by thermocompression bonding, then, the copper foil 22 was processed into a conductive pattern by photolithographic approach; further, another insulating base material 50 and another copper foil 22 were superposed thereon and laminated by thermocompression bonding, then the copper foil 22 was processed into a conductive pattern by photolithographic approach. Still further, the insulating base material 50C having substantially the same cavity hole 15 as that of Example 3 and the copper foil 22 were superposed thereon in the order mentioned and laminated by thermocompression bonding, then, the copper foil 22 was processed into a conductive pattern by photolithographic approach. Thereafter, the insulating base material 50C having a slightly bigger cavity hole 15 than that of Example 3 and the copper foil 22 were superposed in the order mentioned and laminated by thermocompression bonding, then, the copper foil 22 was processed into a conductive pattern by photolithographic approach. Conditions of the sequential lamination were the same as that of Example 3.

With regard to the spacer, when laminating the first wiring substrate 100C, a thinner spacer used in Example 3 was used; while, when laminating the second wiring substrate 100C, a spacer having a size corresponding to the slightly larger cavity hole 15 was superposed (in the manner as the embodiment shown in FIG. 10 and used. In this way, the multilayer wiring substrate 200D having cavity portion 220 of staircase pattern was fabricated.

### Example 5

### (Production of the Insulating Base Material 50E)

A thermoplastic resin composition obtained by mixing: to 100 parts by mass of a resin mixture having: 40 mass % of a polyether ether ketone resin (PEEK 450G, Tm=335° C.), and 60 mass % of an amorphous polyetherimide resin (ULTEM 1000); 35 parts by mass of titanium oxide (average particle diameter of 0.23 μm, alumina treatment, silane coupling treatment) produced by chlorine method; and 30 parts by mass of a synthetic mica having an average particle diameter of 5 μm and an average aspect ratio of 50, was melt-kneaded. Then, the melt-kneaded resin composition was extruded into a film having a thickness of 150 μm simultaneously with lamination of a copper foil 22 from one side, to obtain one-sided copper-laminated insulating base material 50E.

### (Production of the Insulating Base Material 50F)

Substantially the same thermoplastic resin composition as that of the insulating base material 50E was melt-kneaded; simultaneously with extruding a 150 μm thick film of the resin composition, a copper foil 22 was laminated from one side, to obtain a one-sided copper-laminated insulating base material 50E. Then, the one-sided copper-laminated insulating base material 50F was formed by punching out a predetermined shape of cavity hole 15 in the one-sided copper-laminated insulating base material 50E by using Thomson die cutter.

### (Fabrication of the Multilayer Wiring Substrate 200E)

The insulating base material 50E and the insulating base material 50 were superposed and laminated under conditions at 230° C. and a pressure of 5 MPa for 30 minutes by vacuum pressing. Then, through holes having a diameter of 200 μm were formed using a drill, followed by plating. Later, the copper foil was processed into a conductive pattern 20 by photolithographic approach. Thus the multilayer wiring substrate 200E was fabricated.

### Example 6

### (Production of the Insulating Base Material 12)

A thermoplastic resin composition obtained by mixing: to 100 parts by mass of a mixed resin having: 65 mass % of a polyether ether ketone resin (PEEK 450G, Tm=335° C.), and 35 mass % of an amorphous polyetherimide resin (ULTEM 1000); 35 parts by mass of titanium oxide (average particle diameter of 0.23 μm, alumina treatment, silane coupling treatment) produced by chlorine method; and 30 parts by mass of a synthetic mica having an average particle diameter of 5 μm and an average aspect ratio of 50, was melt-kneaded. Then, the melt-kneaded resin composition was extruded into a film having a thickness of 100 μm (i.e. insulating base material). After giving corona discharge treatment to both sides of the obtained film, a solution containing a polymerizable monomer prepared by mixing 50 mass % of dimethallyl bisphenol A and 50 mass % of bis (4-maleimidephenyl)methane was applied on a mold-releasable PET film and solidified by drying to form a 5 μm thick adhesive layer. Then, the adhesive layer was thermally transferred onto both surfaces of the insulating base material 12.

(Production of the Wiring Substrate 100c)

On both side of the insulating base material 12, 12 μm thick copper foil was laminated under conditions at 200° C. and at a pressure of 5 MPa for 30 minutes by using vacuum pressing. Thereafter, through holes having a diameter of 100 μm were formed by using laser and plating for filling the through holes was carried out. Then, the copper foil was processed into a conductive pattern 20 by photolithographic approach. Thus the wiring substrate 100c was obtained.

### (Production of the Multilayer Wiring Substrate 200F)

The insulating base material 12 and the 12 μm thick copper foil were superposed on the wiring substrate 100c and laminated under conditions at 230° C. and a pressure of 5 MPa for 30 minutes, then, via holes having a diameter of 100 μm were formed by using laser. Next, the via holes were filled by plating for forming interlayer wirings, then, the copper foil was processed into a conductive pattern 20 by photolithographic approach. Further, the insulating base material having a cavity hole and the copper foil were laminated, and then via holes were formed; after that, the via holes were filled by plating and a conductive pattern was formed, to obtain the multilayer wiring substrate 200F having two wiring substrate 100c and one wiring substrate 100C.

<Evaluation Method>

The obtained multilayer wiring substrates were evaluated as follows. The evaluation results are shown in Table 1.

(Thermal Resistance under Moisture Absorption)

The multilayer wiring substrates thus obtained were dried at 125° C. for 4 hours. Then, the dried substrates were taken in a constant-temperature and humidity chamber at 30° C. and a humidity of 85% for 96 hours; later, these were heated in a reflow furnace at a peak temperature of 250° C. twice. The obtained multilayer wiring substrates were evaluated based on the following criteria.
◯ (good) : there is no peeling along the lamination interface between the substrates and there is no swelling occured in the via holes.
× (bad) : Peeling is caused along the lamination interface between the substrates and/or swelling is caused in the via hole.

### (Bonding Strength of Conductors)

A wire was soldered to the conductive pattern portion exposed on the multilayer wiring substrate and the wire was upwardly pulled, to measure the strength at a time of peeling the conductive pattern portion.
◯ (good): The strength is 1 N/mm or more.
× (bad): The strength is below 1 N/mm.

### (Average Reflectance)

Integrating sphere was attached to the spectrophotometer (“U-4000” manufactured by Hitachi, Ltd.), and the reflectance of the insulating base material constituting the wiring substrates 100a and 100c within the wavelength of 400-800 nm when the reflectance of an alumina white plate is 100% was measured at 0.5 nm interval. The average value of the obtained measurement values was calculated; then it was determined as the average reflectance.

### (Reflectance After Heating)

After heating (crystallizing) the insulating base material constituting the wiring substrates 100a and 100c in a vacuum press machine at a peak temperature of 260° C. for 30 minutes, the wiring substrates 100a and 100c were heated in a circulating hot air oven at 200° C. for 4 hours and 260 ° C. for 5 minutes, and then the reflectance at 470 nm after heating was measured in the same manner as the above method.

<Evaluation Results >

TABLE 1

| | Thermal | | Average | Reflectance at 470 nm after | | |
|---|---|---|---|---|---|---|
| | resistance | Adhesive | reflectance | Thermal treatment (%) | | |
| | under Moisture | strength of the | (%) | Before | 200° C. for | 260° C. for |
| | absorption | Conductor | (400-800 nm) | treatment | 4 hrs | 5 min |
| Example 1 | ◯ | ◯ | 73 | 71 | 70 | 70 |
| Example 2 | ◯ | ◯ | 73 | 71 | 70 | 70 |
| Example 3 | ◯ | ◯ | 74 | 72 | 71 | 71 |
| Example 4 | ◯ | ◯ | 74 | 72 | 71 | 71 |
| Example 5 | ◯ | ◯ | 82 | 77 | 76 | 76 |
| Example 6 | ◯ | ◯ | 82 | 77 | 76 | 76 |

### INDUSTRIAL APPLICABILITY

The multilayer wiring substrate having a cavity portion (recess) of the invention can be suitably used for a semiconductor chip, particularly for mounting light-emitting diodes (LED elements).

1. A multilayer wiring substrate comprising: a plurality of wiring substrates laminated to each other; and a cavity portion,
in the multilayer wiring substrate, at least one layer of a wiring substrate 1 being arranged at least along the bottom face of the cavity portion and at least one layer of a wiring substrate 2 being arranged at an upper layer side of the wiring substrate 1,
the wiring substrate 1 and/or the wiring substrate 2 respectively comprising an insulating base material which comprises an inorganic filler thermoplastic resin composition as a main component and which has an average reflectance of 70% or more in a wavelength range of 400-800 nm and a decreasing rate in reflectance of 10% or less in a wavelength range of 470 nm after thermal treatment at 200° C. for 4 hours,
the wiring substrate 2 being provided with a cavity hole.

2. A multilayer wiring substrate comprising: a plurality of wiring substrates laminated to each other; and a cavity portion,
in the multilayer wiring substrate, at least one layer of a wiring substrate 1 being arranged at least along the bottom face of the cavity portion and at least one layer of a wiring substrate 2 being arranged at an upper layer side of the wiring substrate 1,
the wiring substrate 1 and/or the wiring substrate 2 respectively comprising an insulating base material which comprises an inorganic filler thermoplastic resin composition as a main component and which has an average reflectance of 70% or more in a wavelength range of 400-800 nm and a decreasing rate in reflectance of 10% or less in a wavelength range of 470 nm after thermal treatment at 200° C. for 4 hours, and which further comprises an adhesive layer comprising a thermosetting resin composition as a main component and being arranged at least one surface of the insulating base material,
the wiring substrate 2 being provided with a cavity hole.

3. The multilayer wiring substrate having a cavity portion according to claim 1,
wherein the wiring substrates 1 and 2 are independently either a wiring substrate where a conductive pattern is formed on at least one surface of the insulating base material and an interlayer wiring is formed in the insulating base material to connect electrically in the thickness direction, or another wiring substrate where an interlayer wiring only is formed in the insulating base material to connect electrically in the thickness direction.

4. The multilayer wiring substrate having a cavity portion according to claim 4, wherein the interlayer wiring comprises a conductive paste composition.

5. The multilayer wiring substrate having a cavity portion according to claim 4, wherein the conductive paste composition comprises a conductive powder and a binder component, wherein the mass ratio of the conductive powder to the binder component is from 90/10 to 98/2,
the conductive powder comprises a first alloy particle and a second metal particle, wherein the first alloy particle is a non-lead solder particle having a melting point of from 130° C. to 260° C., the second metal particle is at least one selected from the group consisting of Au, Ag, and Cu, and the mass ratio of the first alloy particle to the second metal particle is from 76/24 to 90/10,
the binder component is a mixture of thermosetting polymerizable monomers and the melting point of the non-lead solder particle is within the range of setting temperature of the binder component,
storage elastic modulus of the thermoplastic resin composition constituting the insulating base material at the melting point of the non-lead solder particle is from 10 MPa to 5 GPa.

6. The multilayer wiring substrate having a cavity portion according to claim 1, wherein the refractive index of the inorganic filler in the thermoplastic resin composition is 1.6 or more.

7. The multilayer wiring substrate having a cavity portion according to claim 6, wherein the inorganic filler is titanium oxide.

8. The multilayer wiring substrate having a cavity portion according to claim 6, wherein the thermoplastic resin composition further comprising an inorganic filler having an average diameter of 15 μm or less and an average aspect ratio of 30 or more.

9. The multilayer wiring substrate having a cavity portion according to claim 1, wherein the wiring substrate 2 comprises a plurality of wiring substrates and the plurality of wiring substrates respectively have a cavity hole of different size from each other, and the diameter of the cavity hole is expanded toward the upper layer side.

10. The multilayer wiring substrate having cavity portions according to claim 1, wherein the thermoplastic resin composition is a mixed composition which comprises a polyarylketone resin and an amorphous polyetherimide resin and which has a crystal melting peak temperature of 260° C. or more.

11. A method for fabricating a multilayer wiring substrate having a cavity portion by laminating a plurality of wiring substrates, comprising:
A) laminating one or more layers of wiring substrate 1 arranged on the bottom of a cavity portion;
B) laminating one or more layers of wiring substrate 2 arranged on the wiring substrate 1; and
C) integrating these laminated wiring substrates by thermocompression bonding, wherein the wiring substrate 1 and/or the wiring substrate 2 respectively comprise an insulating base material which comprises an inorganic filler thermoplastic resin composition as a main component and which has an average reflectance of 70% or more in the wavelength range of 400-800 nm and a decreasing rate in reflectance of 10% or less in a wavelength range of 470 nm after thermal treatment at 200° C. for 4 hours, and the wiring substrate 2 further comprises a cavity hole.

12. A method for fabricating a multilayer wiring substrate having a cavity portion by laminating a plurality of wiring substrates, comprising:
forming a wiring substrate 1 comprising: an insulating base material 1, an adhesive layer comprising a thermosetting resin composition as a main component and being provided on at least one surface of the insulating base material 1, and a conductive pattern provided on the adhesive layer and/or the insulating base material 1;
forming a monolayer wiring substrate 2 or sequentially forming a multilayer wiring substrate 2 by once or repeatedly: superposing on the wiring substrate 1 an insulating base material 2 where an adhesive layer comprising a thermosetting resin composition as a main component is provided on at least one surface and in which a cavity hole is formed; superposing a copper foil on the insulating base material 2; integrating these layers by thermocompression bonding; and then, etching the copper foil to produce a conductive pattern,
wherein the insulating base material 1 and/or the insulating base material 2 independently comprise an inorganic filler thermoplastic resin composition as a main component and which have an average reflectance of 70% or more in a wavelength range of 400-800 nm and a decreasing rate in reflectance of 10% or less in a wavelength range of 470 nm after thermal treatment at 200° C. for 4 hours.

13. A method for fabricating a multilayer wiring substrate having a cavity portion by laminating a plurality of wiring substrate, comprising:
sequentially forming two or more wiring substrates 1 by once or repeatedly: forming a wiring substrate 1 comprising: an insulating base material 1, an adhesive layer comprising a thermosetting resin composition as a main component and being provided on at least one surface of the insulating base material 1, and a conductive pattern provided on the adhesive layer and/or the insulating base material 1; superposing on the wiring substrate 1 an insulating base material 1 where an adhesive layer comprising a thermosetting resin composition as a main component is provided on at least one surface; superposing a copper foil on the insulating base material 1; integrating these layers by thermocompression bonding; and then, etching the copper foil to produce a conductive pattern,
further, forming a monolayer wiring substrate 2 or sequentially forming a multilayer wiring substrate 2 by once or repeatedly: superposing on the wiring substrate 1 an insulating base material 2 where an adhesive layer comprising a thermosetting resin composition as a main component is provided on at least one surface and in which a cavity hole is formed;
superposing a copper foil on the insulating base material 2; integrating these layers by thermocompression bonding; and then, etching the copper foil to produce a conductive pattern,
wherein the insulating base material 1 and/or the insulating base material 2 independently comprise an inorganic filler thermoplastic resin composition as a main component and have an average reflectance of 70% or more in a wavelength range of 400-800 nm and a decreasing and 21-27 rate in reflectance of 10% or less in a wavelength range of 470 nm after thermal treatment at 200° C. for 4 hours.
